(19) United States
(12) Patent Application Publication
(10) Pub. No.: US 2017/0246690 A1
(43) Pub. Date: Aug. 31, 2017

(54) STABILIZING AGENT-FREE METAL NANOPARTICLE SYNTHESIS AND USES OF METAL NANOPARTICLES SYNTHESIZED THEREFROM

(71) Applicants: RHODIA OPERATIONS, Paris (FR); CENTRE NATIONAL DE LA RECHERCHE SCIENTIFIQUE, PARIS Cedex 16 (FR); UNIVERSITY OF PENNSYLVANIA, PHILADELPHIA, PA (US)

(72) Inventors: Ryan J. MURPHY, Jersey City, NJ (US); Remi DREYFUS, PHILADELPHIA, PA (US); Lawrence Alan HOUGH, Yongsan-gu, Seoul (KR); Ludivine MALASSIS, Philadelphia, PA (US); Christopher MURRAY, Bala Cynwyd Lower Merion, PA (US); Bertrand DONNIO, Narberth, PA (US)

(21) Appl. No.: 15/320,493

(22) PCT Filed: Jun. 19, 2015
(86) PCT No.: PCT/US2015/036583

§ 371 Date: Dec. 20, 2016

Related U.S. Application Data
(60) Provisional application No. 62/015,303, filed on Jun. 20, 2014.
(60) Provisional application No. 62/161,602, filed on May 14, 2015.

(51) Int. Cl. B22F 9/24; B01J 23/52; B01J 37/04; B01J 35/00; B01J 37/00; B01J 37/16; B22F 1/00; B01J 23/50

(52) U.S. Cl. CPC B22F 9/24; B22F 1/0018; B22F 1/0062; B01J 23/52; B01J 23/50; B01J 35/0006; B01J 35/0013; B01J 37/009; B01J 37/16; B01J 37/04; B22F 2009/245; B22F 2301/255; B22F 2302/45; B22F 2303/01; B22F 2304/05; B22F 2998/10; H01L 51/5206

(57) ABSTRACT

Described herein are methods of synthesizing metal nanoparticles and the metal nanoparticles synthesized therefrom. Further described in the present disclosure are methods of modifying the surfaces of metal nanoparticles and the metal nanoparticles modified thereby. Also described herein are uses of such metal nanoparticles.

### CROSS REFERENCE TO RELATED APPLICATIONS

This application claims the priority of U.S. Provisional Application No. 62/015,303 filed Jun. 20, 2014; and U.S. Provisional Application No. 62/161,602 filed May 14, 2015. The entire contents of these applications are explicitly incorporated herein by this reference.

### FIELD OF THE INVENTION

The present invention relates to methods of synthesizing metal nanoparticles and metal nanoparticles synthesized therefrom. The present invention further relates to methods of modifying the surfaces of metal nanoparticles and the metal nanoparticles modified thereby. The present invention also relates to uses of such metal nanoparticles.

### BACKGROUND

For next generation technologies in the areas of medicine, materials science, photonics, and plasmonics, the incorporation of metal nanoparticles into various material or solvent environments is a key technical challenge. Many synthesis protocols of metal nanoparticles are known. However, the problem with incorporating these metal nanoparticles into different material, solvent, or biological environments lies within the chemistry of the surfactant used during such syntheses. The surfactant is present during the synthesis and it is known that after the synthesis is complete, the surfactant partitions to the surface of the metal nanoparticle, and stabilizes them against aggregation via steric hindrance or electrostatic repulsion. If the chemical compatibility of this surfactant does not match with the system one wishes to incorporate the nanoparticle into, the surfactant must be changed. This stabilizing agent exchange process can often be time consuming, low-throughput, and inefficient, and thus limits the industrial or medical impact of metal nanoparticle composite materials for mechanical fillers, optical enhancement, drug delivery agents, and the like.

From the standpoint of post-particle synthesis modification, there are various examples of stabilizing agent exchange reactions that can replace the stabilization agent used during the synthesis with a different system, for example, those reported by Woehrle, G. H. et al., J. Phys. Chem. B., 106, 9979 (2002) and Neouze, M-A., Schubert, U., Monatsh. Chem., 139, 183 (2008). The drawback to these exchange reactions are that often they can be inefficient, meaning the nanoparticle surface will contain a certain fraction of the original stabilization agent that was attempted to be removed. Another drawback to such exchange reactions is that, when the exchange is complete, it is often required to conduct a final cleaning step to rid the solution of residual stabilization agent. In an industrial setting, such additional processing steps could prove quite costly, therefore increasing the barrier-to-entry for these metal nanoparticle systems into various markets.

There is an unresolved interest in developing facile, efficient, and high-throughput methods and processes for the synthesis and/or surface modification of metal nanoparticles for use in diverse technology areas.

### SUMMARY OF THE INVENTION

In a first aspect, the present invention relates to a method for synthesizing metal nanoparticles, the method comprising:
(a) preparing a metal precursor mixture comprising a metal precursor compound and a first aqueous liquid medium,
(b) preparing a reducing agent mixture comprising a reducing agent and a second aqueous liquid medium,
(c) optionally adding an acid or a base to the mixture prepared in step (a) or to the mixture prepared in step (b),
   wherein the metal precursor mixture and the reducing agent mixture are both free of stabilizing agent and free of seed particles,
(d) combining the metal precursor mixture with the reducing agent mixture so as to allow the metal precursor compound to react with the reducing agent,
   and metal nanoparticles synthesized therefrom

In a second aspect, the present invention relates to a method for modifying the surface of metal nanoparticles, the method comprising:
contacting the metal nanoparticles synthesized by the methods described herein with at least one stabilizing agent,
   and metal nanoparticles modified thereby.

In a third aspect, the present invention relates to an electronic device comprising the metal nanoparticles synthesized and/or modified by the methods described herein.

In a fourth aspect, the present invention relates to a catalyst comprising metal nanoparticles synthesized and/or modified by the methods described herein, and, optionally, a support.

### BRIEF DESCRIPTION OF THE DRAWINGS

FIG. 1 shows an electronic device according to an embodiment of the present invention.

FIG. 2 shows metal nanoparticles synthesized according to Example 1.

FIG. 3 shows metal nanoparticles made according to Comparative Example 1.

FIG. 4 shows a comparison of the extinction curves of metal nanoparticles synthesized according to Example 1 and nanoparticles made according to Comparative Example 1.

FIG. 5 shows metal nanoparticles synthesized according to Example 2.

FIG. 6 shows a comparison of the extinction curves of metal nanoparticles synthesized according to Example 1 and nanoparticles made according to Example 2.

FIG. 7 shows TEM images of metal nanoparticles synthesized according to Example 3.

FIG. 8 shows the extinction curves of metal nanoparticles synthesized according to Example 3.

FIG. 9 shows TEM images of metal nanoparticles synthesized according to Example 4.

FIG. 10 shows the extinction curves of metal nanoparticles synthesized according to Example 4.

FIG. 11 shows the extinction spectra of metal nanoparticles with varying amounts of NaOH added following completion of their synthesis.

FIG. 12 shows a superposition of the titration curve of a HAuCl₄ solution at 1.64 M from D. V. Goia, Colloids and Surfaces A: Physicochem. Eng. Aspects 146, 1999, 139 and a titration curve of a HAuCl₄ solution at 0.5 mM according to the present invention.

FIGS. 13 and 14 show the extinction spectra of metal nanoparticles made with varying NaOH/HAuCl₄ ratios.

FIG. 15 shows the evolution of plasmon peak position as a function of NaOH/HAuCl₄ ratio.

FIG. 16 shows the evolution of plasmon peak width (expressed as full width at ¾ of the maximum) as a function of NaOH/HAuCl₄ ratio.

FIG. 17 shows reduced metal nanoparticle concentration as a function of NaOH/HAuCl₄ ratio.

FIG. 18 shows the TEM images of metal nanoparticles made with varying NaOH/HAuCl₄ ratios.

FIG. 19 shows the evolution of metal nanoparticle diameter as a function of NaOH/HAuCl₄ ratio.

FIG. 20 shows the evolution of % polydispersity as a function of NaOH/HAuCl₄ ratio.

FIG. 21 shows a TEM image of silver nanoparticles synthesized according to Example 7.

FIG. 22 shows the extinction spectra of silver nanoparticles synthesized according to Example 7.

FIG. 23-32 show the extinction spectra of metal nanoparticles modified using various surfactants according to an embodiment described in Example 8.

FIG. 33 shows the extinction spectra of metal nanoparticles at various stages of modification according to Example 8.

FIG. 34 shows the extinction spectra of metal nanoparticles modified by using various cationic and anionic surfactants.

FIG. 35 shows the extinction spectra of metal nanoparticles modified by using various nonionic surfactants and polymers.

FIG. 36 shows the extinction curves of nanoparticles modified by various surfactants, including ethoxylated oleyl amine (RHODAMEEN® PN-430).

FIG. 37 shows the TEM images of nanoparticles formed with various R ratios according to Example 10 herein; a) R=0, b) R=1.6, c) R=2.9, and d) R=6.4.

FIG. 38 shows the variation of pH of ascorbic acid solutions as R₂ ratios are varied from 0 to 2.

FIG. 39 shows the extinction spectra of particles synthesized at different R₂ ratios.

FIG. 40 shows the plasmonic peak positions (λₘₐₓ, dots) and the diameters (triangles) of the inventive nanoparticles formed according to Example 11 herein.

FIG. 41 shows the HWHM (half-width at half the maximum; dots) and the polydispersity (triangles) of the inventive nanoparticles formed according to Example 11 herein.

FIG. 42 shows the TEM images of nanoparticles formed with various R₂ ratios according to Example 11 herein; a) R₂=0, b) R₂=0.6, c) R₂=1, d) R₂=1.2, e) R₂=1.6, and f) R₂=2.

FIG. 43 shows a plot of pH as a function of R₃ ratio in the preparation of inventive silver nanoparticles according to Example 12 herein.

FIG. 44 shows the extinction spectra of the inventive nanoparticles synthesized at different R₃ ratios according to Example 12 herein.

FIG. 45 shows the plasmonic peak positions (λₘₐₓ, dots) and the diameters (triangles) of the inventive silver nanoparticles formed according to Example 12 herein.

FIG. 46 shows the HWHM (half-width at half the maximum; dots) and the polydispersity (triangles) of the inventive silver nanoparticles made according to Example 12 herein.

FIG. 47 shows the TEM images of inventive nanoparticles formed with various R₃ ratios according to Example 12 herein; a) R₃=1.44, b) R₃=1.56, c) R₃=1.67, d) R₃=1.78, e) R₃=2, f) R₃=2.22, g) R₃=2.44, and h) R₃=2.67.

### DETAILED DESCRIPTION OF THE INVENTION

As used herein, the terms “a”, “an”, or “the” means “one or more” or “at least one” unless otherwise stated.

As used herein, the term “comprises” includes “consisting essentially of” and “consisting of” unless otherwise stated.

As used herein, the term “(Cₓ-C_{y})” in reference to an organic group, wherein x and y are each integers, means that the group may contain from x carbon atoms to y carbon atoms per group.

The present invention relates to a method for synthesizing metal nanoparticles, the method comprising:
(a) preparing a metal precursor mixture comprising a metal precursor compound and a first aqueous liquid medium,
(b) preparing a reducing agent mixture comprising a reducing agent and a second aqueous liquid medium,
(c) optionally adding an acid or a base to the mixture prepared in step (a) or to the mixture prepared in step (b),
   wherein the metal precursor mixture and the reducing agent mixture are both free of stabilizing agent and free of seed particles,
(d) combining the metal precursor mixture with the reducing agent mixture so as to allow the metal precursor compound to react with the reducing agent,
   thereby synthesizing the metal nanoparticles.

Preparation of the metal precursor mixture may be accomplished using any method known to those skilled in the art. For example, a specified amount of metal precursor compound may be dissolved in an aqueous liquid medium to produce a stock solution, which may be diluted to produce a final mixture having a metal precursor compound concentration suitable for the subsequent reduction reaction. Alternatively, for example, a specified amount of metal precursor compound may be dissolved in an aqueous liquid medium to produce a final mixture having a metal precursor compound concentration suitable for the subsequent reduction reaction.

Preparation of the reducing agent mixture may be accomplished using any method known to those skilled in the art. For example, a specified amount of reducing agent may be dissolved in an aqueous liquid medium to produce a stock solution, which may be diluted to produce a final mixture having a reducing agent concentration suitable for the subsequent reduction reaction. Alternatively, for example, a specified amount of reducing agent may be dissolved in an aqueous liquid medium to produce a final mixture having a metal precursor compound concentration suitable for the subsequent reduction reaction.

The first and second aqueous liquid medium may be the same or different. In an embodiment, first and second aqueous liquid medium are the same.

As used herein, any term modified by the phrase “free of” means that there is no external addition of the material denoted by the term modified and that there is no detectable amount of the material denoted by the term modified. Thus, for example, the term “free of stabilizing agent” means that there is no external addition of stabilizing agent and that there is no detectable amount of stabilizing agent that may be observed by analytical techniques known to the skilled artisan, such as, for example, gas or liquid chromatography, spectrophotometry, and optical microscopy. Examples of stabilizing agents are described herein. In an embodiment, the mixture comprising a metal precursor compound and an aqueous liquid medium is free of stabilizing agents. Similarly, as used herein, the phrase “free of seed particles” means that there is no external addition of seed particles and that there is no detectable amount of seed particles. As used herein, seed particles refer to metal nanoparticles having oxidation state of 0 that are used a nucleation centers for seeded nanoparticle growth. In an embodiment, the mixture comprising a metal precursor compound and an aqueous liquid medium is free of seed particles. In some embodiments, the reducing agent may function as a stabilizing agent. In such embodiments, “free of stabilizing agent” means free of stabilizing agent incapable of reducing the metal precursor compound.

The metal precursor compounds that may be used in the methods described herein include metal-containing compounds capable of being reduced to the corresponding metal (oxidation state=0). Generally, the metal in the metal precursor compound has a positive, non-zero oxidation state prior to being reduced.

Examples of such metals include, but are not limited to, main group metals such as, e.g., lead, tin, antimony and indium, and transition metals, e.g., a transition metal selected from the group consisting of gold, silver, copper, nickel, cobalt, palladium, platinum, iridium, osmium, rhodium, ruthenium, rhenium, vanadium, chromium, manganese, niobium, molybdenum, tungsten, tantalum, iron and cadmium.

In an embodiment, the metal comprises a transition metal.

In an embodiment, the metal comprises gold, silver, platinum, palladium, or iron.

In an embodiment, the metal comprises gold or silver.

Suitable metal precursor compounds include, but are not limited to, metal oxides, metal hydroxides, metal salts of inorganic and organic acids such as, for example, nitrates, nitrites, sulfates, halides (e.g., fluorides, chlorides, bromides and iodides), carbonates, phosphates, azides, borates (including fluoroborates and pyrazolylborates), sulfonates, carboxylates (such as, for example, formates, acetates, propionates, oxalates and citrates), substituted carboxylates (including halogenocarboxylates such as, for example, trifluoroacetates, hydroxycarboxylates, and aminocarboxylates), and metal salts and metal acids wherein the metal is part of an anion (such as, e.g., hexachloroplatinates, tetrachloroplatinates, tetrachloroaurates, hexachloropalladates, tetrachloroferrates, tungstates and the corresponding acids).

Further examples of suitable metal precursor compounds for use in the present invention include alkoxides, complex compounds (e.g., complex salts) of metals such as, e.g., beta-diketonates (e.g., acetylacetonates), complexes with amines, N-heterocyclic compounds (e.g., pyrrole, aziridine, indole, piperidine, morpholine, pyridine, imidazole, piperazine, triazoles, and substituted derivatives thereof), aminoalcohols (e.g., ethanolamine, etc.), amino acids (e.g., glycine, etc.), amides (e.g., formamides, acetamides, etc.), and nitriles (e.g., acetonitrile, etc.).

Examples of specific metal precursor compounds for use in the present invention include silver nitrate, silver nitrite, silver oxide, silver fluoride, silver hydrogen fluoride, silver carbonate, silver oxalate, silver azide, silver tetrafluoroborate, silver acetate, silver propionate, silver butanoate, silver ethylbutanoate, silver pivalate, silver cyclohexanebutanoate, silver ethylhexanoate, silver neodecanoate, silver decanoate, silver trifluoroacetate, silver pentafluoropropionate, silver heptafluorobutyrate, silver trichloroacetate, silver 6,6,7,7,8,8,8-heptafluoro-2,2-dimethyl-3,5-octanedionate, silver lactate, silver citrate, silver glycolate, silver glyconate, silver benzoate, silver salicylate, silver phenylacetate, silver nitrophenylacetate, silver dinitrophenylacetate, silver difluorophenylacetate, silver 2-fluoro-5-nitrobenzoate, silver acetylacetonate, silver hexafluoroacetylacetonate, silver trifluoroacetylacetonate, silver tosylate, silver triflate, silver trispyrazolylborate, silver tris(dimethylpyrazolyl)borate, silver ammine complexes, trialkylphosphine and triarylphosphine derivatives of silver carboxylates, silver beta-diketonates, silver beta-diketonate olefin complexes and silver cyclopentadienides; platinum formate, platinum acetate, platinum propionate, platinum carbonate, platinum nitrate, platinum perchlorate, platinum benzoate, platinum neodecanoate, platinum oxalate, ammonium hexafluoroplatinate, ammonium tetrachloroplatinate, sodium hexafluoroplatinate, potassium hexafluoroplatinate, sodium tetrachloroplatinate, dihydrogen tetrachloroplatinate, potassium hexabromoplatinate, hexachloroplatinic acid, hexabromoplatinic acid, dihydrogen hexahydroxoplatinate, diammine platinum chloride, tetraammine platinum chloride, tetraammine platinum hydroxide, tetraammine platinum tetrachloroplatinate, platinum(II) 2,4-pentanedionate, diplatinum trisdibenzylideneacetonate, platinum sulfate and platinum divinyltetramethyldisiloxane; gold(III) acetate, gold(III) chloride, tetrachloroauric acid, gold azide, gold isocyanide, gold acetoacetate, imidazole gold ethylhexanoate and gold hydroxide acetate isobutyrate; palladium acetate, palladium propionate, palladium ethylhexanoate, palladium neodecanoate, palladium trifluoracetate, palladium oxalate, palladium nitrate, palladium chloride, tetraammine palladium hydroxide, tetraammine palladium nitrate, chloropalladic acid (dihydrogen hexachloropalladate), and tetraammine palladium tetrachloropalladate; iron(II) acetate, tetrachloroferric acid (HFeCl4), iron(II) bromide, iron(III) bromide, iron(II) chloride, iron(III) chloride, iron(II) iodide, iron(II) oxalate, iron(III) oxalate, iron(II) sulfate, iron(III) sulfate, and potassium hexacyanoferrate(II).

The above compounds may be employed as such or optionally as their hydrates. The above compounds may also be employed as mixtures thereof.

In an embodiment, the metal precursor compound comprises a metal salt or metal acid wherein the metal is part of an anion.

In an embodiment, the metal precursor compound comprises silver nitrate, tetrachloroauric acid, hexachloroplatinic acid, chloropalladic acid, tetrachloroferric acid (HFeCl₄), or a hydrate thereof.

In an embodiment, the metal precursor compound comprises silver nitrate, tetrachloroauric acid, or a hydrate thereof.

The aqueous liquid medium comprises water and, optionally, one or more water miscible organic liquids. Suitable water miscible organic liquids include polar aprotic organic solvents, such as, for example, dimethyl sulfoxide and dimethyl 2-methylglutarate (marketed as Rhodiasolv® IRIS), polar protic organic solvents, such as, for example, methanol, ethanol, propanol, ethylene glycol, and propylene glycol, and mixtures thereof.

Typically, the aqueous liquid medium comprises, based on 100 wt % of the liquid medium, from about 10 to 100 wt %, more typically from about 50 to 100 wt %, and even more typically, from about 90 to 100 wt %, water and from 0 to about 90 wt %, more typically from 0 pbw to about 50 wt %, and even more typically from 0 to about 10 wt % of one or more water miscible organic liquids.

In one embodiment, the aqueous liquid medium consists essentially of water.

In one embodiment, the aqueous liquid medium consists of water.

In accordance with the methods described herein, an acid or a base may optionally be added to the metal precursor mixture or to the reducing agent mixture. As would be recognized by the skilled artisan, the pH of the metal precursor mixture, the reducing agent mixture, and/or the combined reaction mixture may be altered by the optional addition of an acid or a base.

Examples of acids suitable for use in the methods described herein include, but are not limited to, hydrochloric acid, sulfuric acid, phosphoric acid, nitric acid, hydrofluoric acid, hydrobromic acid, acetic acid, and chloric acid.

In an embodiment, a base is added to the metal precursor mixture or to the reducing agent mixture.

Examples of bases suitable for use in the methods described herein include, but are not limited to, carbonates, hydroxides, and the like. The skilled artisan will recognize that the carbonate and hydroxide bases must also contain a counterion. Exemplary counterions include, but are not limited to, ammonium, sodium, potassium, calcium and the like.

In an embodiment, the base added to the metal precursor mixture or to the reducing agent mixture comprises a hydroxide ion.

In an embodiment, the base added to the metal precursor mixture or to the reducing agent mixture comprises sodium hydroxide.

In an embodiment, a base is added to the metal precursor mixture prepared in step (a) prior to combining with the reducing agent mixture.

In another embodiment, a base is added to the reducing agent mixture prepared in step (b) prior to combining with the metal precursor mixture.

In some embodiments, when a base is added to the metal precursor mixture or to the reducing agent mixture, the molar ratio of base-to-metal precursor compound is typically less than about 4.4:1, more typically less than about 3.0:1, even more typically less than about 2.0:1. In some embodiments, the molar ratio of base-to-metal precursor compound is typically greater than about 4.5:1, more typically greater than about 4.6:1, even more typically greater than about 4.8:1.

In some embodiments, when a base is added to the metal precursor mixture or to the reducing agent mixture, the molar ratio of base-to-metal precursor compound is typically from about 0.1:1 to about 6.0:1, more typically from about 0.1:1 to about 5.4:1.

In some embodiments, the molar ratio of base-to-metal precursor compound is typically from about 0.1:1 to about 4.4:1, more typically from about 0.1:1 to about 3.0:1, even more typically from 0.1:1 to about 2.0:1. In some embodiments, the molar ratio of base-to-metal precursor compound is typically from about 4.5:1 to about 6.0:1, more typically from about 4.6:1 to about 6.0:1, even more typically from 4.8:1 to about 6.0:1.

In some embodiments, when a base is added to the metal precursor mixture or to the reducing agent mixture, the molar ratio of base-to-reducing agent is from about 0:1 to about 3:1, typically from about 0.1:1 to about 3:1. In an embodiment, the molar ratio of base-to-reducing agent is from about 0.1:1 to about 1:1. In another embodiment, the molar ratio of base-to-reducing agent is from about 1:1 to about 2:1. In yet another embodiment, the molar ratio of base-to-reducing agent is from about 1:1 to about 3:1, typically about 1.3:1 to 3:1.

As described herein, the metal precursor mixture is combined with the reducing agent mixture so as to allow the metal precursor compound to react with the reducing agent.

The metal precursor mixture may be combined with the reducing agent mixture using any method known to persons with skill in the art. For example, the metal precursor mixture may be introduced into the reducing agent mixture while the reducing agent mixture is being stirred. Alternatively, the reducing agent mixture may be introduced into the metal precursor mixture while the metal precursor mixture is being stirred.

Reducing agents used in the methods described herein include, for example, polyols, such (alkylene)glycols (e.g., ethylene glycol, propylene glycol and the butylene glycols); hydrazine and derivatives thereof; hydroxylamine and derivatives thereof, monohydric alcohols such as, e.g, methanol and ethanol, aldehydes such as, e.g., formaldehyde, ammonium formate, formic acid, acetaldehyde, and propionaldehyde, or salts thereof (e.g., ammonium formate); hypophosphites; sulfites; tetrahydroborates (such as, e.g., the tetrahydroborates of Li, Na, K); lithium aluminum hydride (LiAIN; sodium borohydride (NaBH₄); polyhydroxybenzenes such as, e.g., hydroquinone, alkyl-substituted hydroquinones, catechols and pyrogallol; phenylenediamines and derivatives thereof; aminophenols and derivatives thereof; carboxylic acids and derivatives thereof such as, e.g., ascorbic acid, ascorbate salts, citric acid, citrate salts, erythorbic acid, erythorbate salts, and ascorbic acid ketals; 3-pyrazolidone and derivatives thereof; hydroxytetronic acid, hydroxytetronamide and derivatives thereof; bisnaphthols and derivatives thereof; sulfonamidophenols and derivatives thereof; and Li, Na and K.

In an embodiment, the reducing agent comprises a carboxylic acid, or a derivative thereof.

In an embodiment, the reducing agent comprises ascorbic acid, citric acid, erythorbic acid, or a salt thereof.

In an embodiment, the reducing agent comprises ascorbic acid, or a salt thereof.

The skilled artisan will recognize, however, that there are other reducing agents that may be employed in the present invention, so long as they are able to reduce the metal precursor compound to a metal.

The total amount of metal precursor compound in the reaction mixture over the entire course of the reaction, based on one liter of reaction mixture, is typically from about 0.1×10⁻³ mole to about 2.0×10⁻³ mole of the metal precursor compound, more typically from greater than or equal to 0.2×10⁻³ mole to about 1.5×10⁻³ mole of the metal precursor compound, even more typically from greater than or equal to 0.4×10⁻³ mole to about 1.0×10⁻³ mole of the metal precursor compound.

The amount of reducing agent used in the reaction is an amount effective to reduce all or a substantial portion of the metal precursor compound. The amount of reducing agent used in the reaction, based on one liter of reaction mixture, is typically from about 0.1×10⁻³ mole to about 32.0×10⁻³ mole, more typically from greater than or equal to 0.6×10⁻³ mole to about 7.0×10⁻³ mole, even more typically from greater than or equal to 0.8×10⁻³ mole to about 2.0×10⁻³ mole of the reducing agent.

The molar ratio of reducing agent-to-metal precursor compound is from typically from about 0.5:1 to about 16:1. More typically, the molar ratio of reducing agent-to-metal precursor compound is from about 1:1 to about 2:1.

The temperature at which the reaction is conducted influences the morphology of the metal nanoparticles formed. Thus, the temperature of the reaction process from the beginning to the end should be carefully controlled. The reaction temperature is typically from about 3° C. to about 35° C., more typically from about 25° C. to about 30° C.

In the methods described herein, the formation of the metal nanoparticles occurs typically on the order of a few minutes. Typically, a substantial percentage of the metal precursor compound is converted to the corresponding metal nanoparticles at a reaction temperature from about 3° C. to about 35° C. in from about 2 minutes to about 24 hours, e.g., from about 30 minutes to about 90 minutes, or from about 45 to about 60 minutes.

The methods described herein may be carried out under exposure to air atmosphere. However, to minimize side reactions, it may be advantageous to conduct the reaction that produces the metal nanoparticles under an inert atmosphere (e.g., under argon and nitrogen gas). In an embodiment, the methods described herein are conducted under air atmosphere.

The dimensions referred to herein in regard to metal nanoparticles synthesized are averaged dimensions obtained by using electron microscopy, such as, for example, transmission electron microscopy (TEM) and scanning electron microscopy (SEM); surface plasmon resonance spectroscopy, UV-vis spectroscopy, or dynamic light scattering using methods known to those of ordinary skill in the art. Dimensions, for example, diameters, may be expressed as weighted averages or as arithmetic averages. For example, the arithmetic average diameter may be calculated by summing the diameters and dividing by the number of nanoparticles examined. For the weighted average diameter, the diameter of each nanoparticle is determined (eg., by TEM) and divided by the sum of the diameters of all nanoparticles measured to derive a quantity W₁, which is the percent contribution of the single nanoparticle to the sum diameter of all nanoparticles, then, for each of the measured nanoparticles, deriving a weighted diameter by multiplying the diameter of the nanoparticle by its respective W₁ value, and finally taking the arithmetic average of the weighted diameters of the measured nanoparticles to derive the weighted average diameter of the nanoparticle population. Unless otherwise indicated, nanoparticle dimensions, including, but not limited to, diameters, are given as arithmetic averages of the measured nanoparticle population. For example, the diameters of a population of nanoparticles (for example, about 200 nanoparticles) may be determined using transmission electron microscopy. The diameter distributions of the nanoparticles synthesized by the methods described herein may be determined using the image analysis software “ImageJ”.

As used herein, an average dimension, for example, average diameter, may be followed by the expression “±σ”, where a represents the standard deviation, which is known by those skilled in the art to describe the amount of variation, or dispersion, from the average.

As used herein, the term “polydispersity” refers to the degree of heterogeneity of a population of nanoparticles examined based on a certain dimension. The term “% polydispersity”, as used herein, is given by the relation: (σ/average value)×100% where a refers to the standard deviation and the “average value” refers to the arithmetic average of the dimension being examined. Unless otherwise indicated, “% polydispersity” as used herein means % polydispersity based on nanoparticle average diameter.

The average diameter of the metal nanoparticles of the present invention is typically less than or equal to 2000 nm, more typically less than or equal to 500 nm, even more typically, less than or equal to 250 nm, or less than or equal to 100 nm, or less than or equal to 50 nm, or less than or equal to 25 nm. In an embodiment, the average diameter is less than or equal to 250 nm. Typically, the average diameter of the metal nanoparticles described herein is from about 25 nm to about 250 nm, more typically from about 25 nm to about 240 nm, even more typically from about 25 nm to about 80 nm.

The polydispersity of the metal nanoparticles of the present invention is typically from about 1% to about 70%, more typically from about 5% to about 60%, even more typically, from about 10% to about 55%.

The metal nanoparticles synthesized as described herein may remain dispersed in the aqueous liquid medium for greater than or equal to 24 hours. In an embodiment, the metal nanoparticles synthesized may remain dispersed in the aqueous liquid medium for greater than or equal to 7 days.

The pH of the reaction mixture after the completion of the reaction may also be altered by the addition of an acid or a base, such as, for example, those described herein. Typically, the pH of the reaction mixture at the end of the reaction is about 2.7. The pH may be increased by the addition of a base to at least 7.5 while maintaining stability of the metal nanoparticles.

The present invention also relates to a method for modifying the surface of metal nanoparticles, the method comprising:
contacting the metal nanoparticles synthesized in accordance with the present invention with at least one stabilizing agent,
   thereby modifying the surface of the metal nanoparticles.

Stabilizing agents include, for example, phosphines; phosphine oxides; alkyl phosphonic acids; polymers, such as polyalkylpolyoxyalkyl polyacrylates, polyvinylpyrrolidones (eg. PVP-10K), polyvinyl acetates, poly(vinylalcohol), polystyrene, and polymethacrylate; polymeric acids, such as polyacrylic acid; alkyl thiols, such as (C₄-C₁₂) thiols; alkyl amines, such as (C₄-C₁₂) amines; carboxylic acids, such as acetic acid, citric acid, and ascorbic acid; fatty acids, such as (C₆-C₂₄) fatty acids; surfactants; dendrimers, and salts and combinations thereof.

(C₄-C₁₂) thiols, include, but are not limited to, ethanethiol, propanethiol, butanethiol, and dodecanethiol.

(C₄-C₁₂) amines, include, but are not limited to, butylamine, sec-butylamine, isobutylamine, tert-butylamine, 3-methoxypropylamine, (2-methylbutyl)amine, 1,2-dimethylpropylamine, 1-ethylpropylamine, 2-aminopentane, amylamine, isopentylamine, pentylamine, tert-amylamine, 3-ethoxypropylamine, 3,3-dimethylbutylamine, hexylamine, 3-isopropoxypropylamine, heptylamine, 2-heptylamine, 1,4-dimethylpentylamine, 1,5-dimethylhexylamine, 1-methylheptylamine, 2-ethyl-1-hexylamine, octylamine, 1,1,3,3-tetramethylbutylamine, nonylamine, decylamine, dodecylamine, tridecylamine, tetradecylamine, hexadecylamine, oleylamine, and octadecylamine.

(C₆-C₂₄) fatty acids include, but are not limited to, hexanoic acid, heptanoic acid, octanoic acid, nonanoic acid, decanoic acid, undecanoic acid, dodecanoic acid, tridecanoic acid, myristic acid, pentadecanoic acid, palmitic acid, oleic acid, heptadecanoic acid, stearic acid, nonadecanoic acid, arachidic acid, heneicosanoic acid, behenic acid, tricosanoic acid, lignoceric acid, pamoic acid, hexacosanoic acid, 8-methylnonanoic acid, 11-methyllauric acid, 12-methyltridecanoic acid, 12-methyltetradecanoic acid, 13-methylmyristic acid, isopalmitic acid, 14-methylhexadecanoic acid, 15-methylpalmitic acid, 16-methylheptadecanoic acid, 17-methylstearic acid, 18-methylnonadecanoic acid, phytanic acid, 19-methylarachidic acid, and isostearic acid.

Surfactants include, for example, anionic surfactants, cationic surfactants, nonionic surfactants, amphoteric or zwitterionic surfactants.

Anionic surfactants include, for example, alkyl sulfates (eg., dodecylsulfate), alkylamide sulfates, fatty alcohol sulfates, secondary alkyl sulfates, paraffin sulfonates, alkyl ether sulfates, alkylpolyglycol ether sulfates, fatty alcohol ether sulfates, alkylbenzenesulfonates, alkylphenol ether sulfates, alkyl phosphates; alkyl or alkylaryl monoesters, diesters, and triesters of phosphoric acid; alkyl ether phosphates, alkoxylated fatty alcohol esters of phosphoric acid, alkylpolyglycol ether phosphates (for example, polyoxyethylene octadecenyl ether phosphates marketed as LUBRHOPHOS® LB-400 by Rhodia), phosphonic esters, sulfosuccinic diesters, sulfosuccinic monoesters, alkoxylated sulfosuccinic monoesters, sulfosuccinimides, α-olefinsulfonates, alkyl carboxylates, alkyl ether carboxylates, alkyl-polyglycol carboxylates, fatty acid isethionate, fatty acid methyltauride, fatty acid sarcoside, alkyl sulfonates (eg., 2-(methyloleoylamino)ethane-1-sulfonate, marketed as GEROPON® T77 by Solvay) alkyl ester sulfonates, arylsulfonates (eg., diphenyl oxide sulfonate, marketed as RHODACAL® DSB by Rhodia), naphthalenesulfonates, alkyl glyceryl ether sulfonates, polyacrylates, α-sulfo-fatty acid esters, and salts and mixtures thereof.

Cationic surfactants include, for example, aliphatic, cycloaliphatic or aromatic primary, secondary and tertiary ammonium salts or alkanolammonium salts; quaternary ammonium salts, such as tetraoctylammonium halides and cetyltrimethylammonium halides (eg., cetyltrimethylammonium bromide (CTAB)); pyridinium salts, oxazolium salts, thiazolium salts, salts of amine oxides, sulfonium salts, quinolinium salts, isoquinolinium salts, tropylium salts.

Other cationic surfactants suitable for use according to the present disclosure include cationic ethoxylated fatty amines. Examples of cationic ethoxylated fatty amines include, but are not limited to, ethoxylated oleyl amine (marketed as RHODAMEEN® PN-430 by Solvay), hydrogenated tallow amine ethoxylate, and tallow amine ethoxylate.

Nonionic surfactants include, for example, alcohol alkoxylates (for example, ethoxylated propoxylated C₈-C₁₀ alcohols marketed as ANTAROX® BL-225 and ethoxylated propoxylated C₁₀-C₁₆ alcohols marketed as ANTAROX® RA-40 by Rhodia), fatty alcohol polyglycol ethers, fatty acid alkoxylates, fatty acid polyglycol esters, glyceride monoalkoxylates, alkanolamides, fatty acid alkylolamides, alkoxylated alkanol-amides, fatty acid alkylolamido alkoxylates, imidazolines, ethylene oxide-propylene oxide block copolymers (for example, EO/PO block copolymer marketed as ANTAROX® L-64 by Rhodia), alkylphenol alkoxylates (for example, ethoxylated nonylphenol marketed as IGEPAL® CO-630 and ethoxylated dinonylphenol/nonylphenol marketed as IGEPAL® DM-530 by Rhodia), alkyl glucosides, alkoxylated sorbitan esters (for example, ethoxylated sobitan monooleate marketed as ALKAMULS® PSMO by Rhodia), alkyl thio alkoxylates (for example, alkyl thio ethoxylates marketed as ALCODET® by Rhodia), amine alkoxylates, and mixtures thereof.

Typically, nonionic surfactants include addition products of ethylene oxide, propylene oxide, styrene oxide, and/or butylene oxide onto compounds having an acidic hydrogen atom, such as, for example, fatty alcohols, alkylphenols or alcohols. Examples are addition products of ethylene oxide and/or propylene oxide onto linear or branched fatty alcohols having from 1 to 35 carbon atoms, onto fatty acids having from 6 to 30 carbon atoms and onto alkylphenols having from 4 to 35 carbon atoms in the alkyl group; (C₆-C₃₀)-fatty acid monoesters and diesters of addition products of ethylene oxide and/or propylene oxide onto glycerol; glycerol monoesters and diesters and sorbitan monoesters, diesters and triesters of saturated and unsaturated fatty acids having from 6 to 22 carbon atoms and their ethylene oxide and/or propylene oxide addition products, and the corresponding polyglycerol-based compounds; and alkyl monoglycosides and oligoglycosides having from 8 to 22 carbon atoms in the alkyl radical and their ethoxylated or propoxylated analogues.

Amphoteric or zwitterionic surfactants include, but are not limited to, aliphatic quaternary ammonium, phosphonium, and sulfonium compounds, wherein the aliphatic radicals can be straight chain or branched, and wherein the aliphatic substituents contains about 6 to about 30 carbon atoms and at least one aliphatic substituent contains an anionic functional group, such as carboxy, sulfonate, sulfate, phosphate, phosphonate, and salts and mixtures thereof. Examples of zwitterionic surfactants include, but are not limited to, alkyl betaines, alkyl amidopropyl betaines, alkyl sulphobetaines, alkyl glycinates, alkyl carboxyglycinates; alkyl amphopropionates, such as cocoamphopropionate and caprylamphodipropionate (marketed as MIRANOL® JBS by Rhodia); alkyl amidopropyl hydroxysultaines, acyl taurates, and acyl glutamates, wherein the alkyl and acyl groups have from 6 to 18 carbon atoms, and salts and mixtures thereof.

In an embodiment, the stabilizing agent is a surfactant or a polymer.

In an embodiment, the surfactant is cationic, anionic, or nonionic.

Contacting the metal nanoparticles with at least one stabilizing agent may be accomplished by any method known to those skilled in the art. In an embodiment, contacting the metal nanoparticles with at least one stabilizing agent comprises (1) adding the at least one stabilizing agent or a stabilizing agent mixture, comprising the at least one stabilizing agent and a first liquid medium, to a nanoparticle mixture, comprising the metal nanoparticles and a second liquid medium, (2) centrifuging the combination formed in step (1), and (3) removing the supernatant.

In an embodiment, the first liquid medium is an aqueous liquid medium as described herein. In an embodiment, the second liquid medium is an aqueous liquid medium as described herein. The first liquid medium and the second liquid medium may be the same or different.

In an embodiment, steps (1)-(3) may optionally be repeated wherein more of the at least one stabilizing agent or stabilizing agent mixture is added to the resulting sedimented metal nanoparticles, thereby re-suspending them. The resulting combination is then centrifuged, after which the supernatant is again removed. Steps (1)-(3) may be repeated as often as needed by the skilled artisan depending on the particular application.

In an embodiment, the method further comprises dispersing the sedimented metal nanoparticles in water.

In an embodiment, the method for modifying the surface of metal nanoparticles comprises:
contacting the metal nanoparticles with at least one stabilizing agent, wherein the metal nanoparticles are synthesized by a method comprising:
   (a) preparing a metal precursor mixture comprising a metal precursor compound and a first aqueous liquid medium,
   (b) preparing a reducing agent mixture comprising a reducing agent and a second aqueous liquid medium,
   (c) optionally adding an acid or a base to the mixture prepared in step (a) or to the mixture prepared in step (b),
      wherein the metal precursor mixture and the reducing agent mixture are both free of stabilizing agent and free of seed particles,
   (d) combining the metal precursor mixture with the reducing agent mixture so as to allow the metal precursor compound to react with the reducing agent;
thereby modifying the surface of the metal nanoparticles.

In an embodiment, the method for modifying the surface of metal nanoparticles comprises:
(1) adding the at least one stabilizing agent or a stabilizing agent mixture, comprising the at least one stabilizing agent and a first liquid medium, to a nanoparticle mixture, comprising the metal nanoparticles and a second liquid medium; wherein
   the metal nanoparticles are synthesized by a method comprising:
   (a) preparing a metal precursor mixture comprising a metal precursor compound and a first aqueous liquid medium,
   (b) preparing a reducing agent mixture comprising a reducing agent and a second aqueous liquid medium,
   (c) optionally adding an acid or a base to the mixture prepared in step (a) or to the mixture prepared in step (b),
      wherein the metal precursor mixture and the reducing agent mixture are both free of stabilizing agent and free of seed particles,
   (d) combining the metal precursor mixture with the reducing agent mixture so as to allow the metal precursor compound to react with the reducing agent;
(2) centrifuging the combination formed in step (1), and
(3) removing the supernatant,
   thereby modifying the surface of the metal nanoparticles.

The present invention relates to the metal nanoparticles synthesized or modified, or both, by the methods described herein and uses thereof.

The present invention relates to an electronic device comprising the metal nanoparticles synthesized or modified, or both, by the methods described herein.

The electronic device of the present invention may be any device that comprises one or more layers of semiconductor materials and makes use of the controlled motion of electrons through such one or more layers, such as, for example:
a device that converts electrical energy into radiation, such as, for example, a light-emitting diode, light emitting diode display, diode laser, a liquid crystal display, or lighting panel,
a device that detects signals through electronic methods, such as, for example, a photodetector, photoconductive cell, photoresistor, photoswitch, phototransistor, phototube, infrared (“IR”) detector, biosensor, or a touch screen display device,
a device that converts radiation into electrical energy, such as, for example, a photovoltaic device or solar cell, and
a device that includes one or more electronic components with one or more semiconductor layers, such as, for example, a transistor or diode.

As used herein, the following terms have the meanings ascribed below:
“anode” means an electrode that is more efficient for injecting holes compared to than a given cathode,
“buffer layer” generically refers to electrically conductive or semiconductive materials or structures that have one or more functions in an electronic device, including but not limited to, planarization of an adjacent structure in the device, such as an underlying layer, charge transport and/or charge injection properties, scavenging of impurities such as oxygen or metal ions, and other aspects to facilitate or to improve the performance of the electronic device,
“cathode” means an electrode that is particularly efficient for injecting electrons or negative charge carriers,
“confinement layer” means a layer that discourages or prevents quenching reactions at layer interfaces,
“electrically conductive” includes conductive and semi-conductive,
“electrically conductive polymer” means any polymer or polymer blend that is inherently or intrinsically, without the addition of electrically conductive fillers such as carbon black or conductive metal particles, capable of electrical conductivity, more typically to any polymer or oligomer that exhibits a bulk specific conductance of greater than or equal to 10⁻⁷ Siemens per centimeter (“S/cm”), unless otherwise indicated, a reference herein to an “electrically conductive polymer” include any optional polymer acid dopant,
“doped” as used herein in reference to an electrically conductive polymer means that the electrically conductive polymer has been combined with a polymer counterion for the electrically conductive polymer, which polymer counterion is referred to herein as “dopant”, and is typically a polymeric acid, which is referred to herein as a “polymeric acid dopant”,
“doped electrically conductive polymer” means a polymer blend comprising an electrically conductive polymer and a polymer counterion for the electrically conductive polymer,
“electroactive” when used herein in reference to a material or structure, means that the material or structure exhibits electronic or electro-radiative properties, such as emitting radiation or exhibiting a change in concentration of electron-hole pairs when receiving radiation,
“electronic device” means a device that comprises one or more layers comprising one or more semiconductor materials and makes use of the controlled motion of electrons through the one or more layers,
“electron injection/transport”, as used herein in reference to a material or structure, means that such material or structure that promotes or facilitates migration of negative charges through such material or structure into another material or structure,
“hole transport” when used herein when referring to a material or structure, means such material or structure facilitates migration of positive charges through the thickness of such material or structure with relative efficiency and small loss of charge,
“layer” as used herein in reference to an electronic device, means a coating covering a desired area of the device, wherein the area is not limited by size, that is, the area covered by the layer can, for example, be as large as an entire device, be as large as a specific functional area of the device, such as the actual visual display, or be as small as a single sub-pixel,
“polymer” includes homopolymers and copolymers,
“polymer blend” means a blend of two or more polymers.

In one embodiment, the electrode layer of an electronic device comprises the metal nanoparticles synthesized or modified, or both, by the methods described herein.

In one embodiment, the buffer layer of an electronic device comprises the metal nanoparticles synthesized or modified, or both, by the methods described herein.

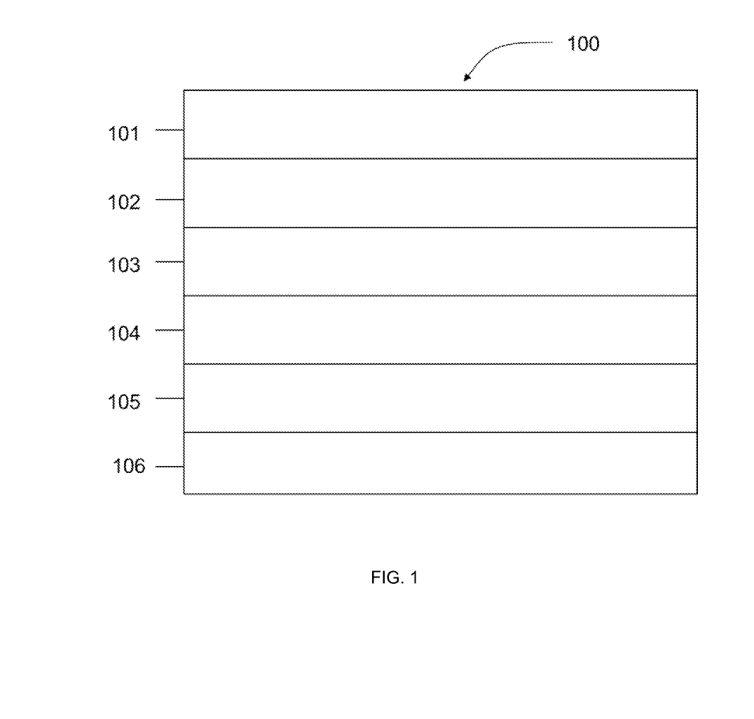

In one embodiment, the electronic device in accordance with the present invention is an electronic device 100, as shown in FIG. 1, having an anode layer 101, an electroactive layer 104, and a cathode layer 106 and optionally further having a buffer layer 102, hole transport layer 103, and/or electron injection/transport layer or confinement layer 105, wherein at least one of the layers of the device comprises the metal nanoparticles synthesized or modified, or both, by the methods described herein. The device 100 may further include a support or substrate (not shown), that can be adjacent to the anode layer 101 or the cathode layer 106. The support can be flexible or rigid, organic or inorganic. Suitable support materials include, for example, glass, ceramic, metal, plastic films, and combinations thereof.

In one embodiment, anode layer 101 itself has a multilayer structure and comprises a layer that comprises the metal nanoparticles synthesized or modified, or both, by the methods described herein, typically as the top layer of the multilayer anode, and one or more additional layers, each comprising a metal, mixed metal, alloy, metal oxide, or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 101 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 101 include, but are not limited to, indium-tin-oxide, indium-zinc-oxide, aluminum-tin-oxide, gold, silver, copper, and nickel. The mixed oxide layer may be formed by a chemical or physical vapor deposition process or spin-cast process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include radio frequency magnetron sputtering and inductively-coupled plasma physical vapor deposition (“IMP-PVD”). These deposition techniques are well known within the semiconductor fabrication arts.

In one embodiment, the mixed oxide layer is patterned. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other methods for patterning that are well known in the art can also be used.

In one embodiment, device 100 comprises a buffer layer 102 and the buffer layer 102 comprises metal nanoparticles synthesized or modified, or both, by the methods described herein.

In one embodiment, a separate buffer layer 102 is absent and anode layer 101 functions as a combined anode and buffer layer. In one embodiment, the combined anode/buffer layer 101 comprises metal nanoparticles synthesized or modified, or both, by the methods described herein.

The layers of the electronic device that comprise metal nanoparticles synthesized or modified, or both, by the methods described herein may be formed by any method known to persons skilled in the art.

In an embodiment, a composition comprising a liquid carrier, metal nanoparticles synthesized or modified, or both, by the methods described herein, and, optionally, one or more additives, is deposited on a substrate or on a formed layer, for example, by casting, spray coating, spin coating, gravure coating, curtain coating, dip coating, slot-die coating, ink jet printing, gravure printing, or screen printing. The liquid carrier is then removed from the layer. Typically, the liquid carrier is removed from the layer by allowing the liquid carrier component of the layer to evaporate. In the case of a substrate supported layer, the layer may be subjected to elevated temperature to encourage evaporation of the liquid carrier. The liquid carrier component of the composition may be any liquid in which the metal nanoparticles synthesized or modified, or both, by the methods described herein are dispersible. In an embodiment, the liquid carrier is an aqueous liquid medium as described herein.

Suitable additives include, but are not limited to, electrically conductive materials, such as, for example, electrically-conductive polymers, graphite particles, including graphite fibers, or carbon particles, including carbon fullerenes and carbon nanotubes, and as well as combinations of any such additives.

Examples of suitable electrically-conductive polymers include, but are not limited to, electrically conductive polythiophene polymers (eg., poly(3,4-ethylenedioxythiophene), more typically referred to as “PEDOT”, and poly(3-hexylthiophene)), electrically conductive poly(selenophene) polymers, electrically conductive poly(telurophene) polymers, electrically conductive polypyrrole polymers, electrically conductive polyaniline polymers (eg., unsubstituted polyaniline, more typically referred to as “PANI”), electrically conductive fused polycylic heteroaromatic polymers, and blends of any such polymers. Methods for making such polymers are generally known.

The electrically-conductive polymers may comprise homopolymers, one or more copolymers of two or more respective monomers, or a mixture of one or more homopolymers and one or more copolymers. The electrically-conductive polymers may each comprise a single polymer or may comprise a blend two or more polymers which differ from each other in some respect, for example, in respect to composition, structure, or molecular weight.

The electrically-conductive polymers may further comprise one or more polymeric acid dopants. Some non-limiting examples of polymeric acid dopants include polymeric sulfonic acids (eg., poly(styrene sulfonic acid) and poly(acrylamido-2-methyl-1-propane-sulfonic acid)); and polycarboxylic acids (eg., polyacrylic acid, polymethacrylic acid, polymaleic acid, and the like).

Suitable fullerenes include for example, C60, C70, and C84 fullerenes, each of which may be derivatized, for example with a (3-methoxycarbonyl)-propyl-phenyl (“PCBM”) group, such as C60-PCBM, C70-PCBM and C-84 PCBM derivatized fullerenes. Suitable carbon nanotubes include single wall carbon nanotubes having an armchair, zigzag or chiral structure, as well as multiwall carbon nanotubes, including double wall carbon nanotubes, and mixtures thereof.

In some embodiments, optional hole transport layer 103 is present, either between anode layer 101 and electroactive layer 104, or, in those embodiments that comprise buffer layer 102, between buffer layer 102 and electroactive layer 104. Hole transport layer 103 may comprise one or more hole transporting molecules and/or polymers. Commonly used hole transporting molecules include, but are not limited to: 4,4′,4″-tris(N,N-diphenyl-amino)-triphenylamine, 4,4′,4″-tris(N-3-methylphenyl-N-phenyl-amino)-triphenylamine, N,N′-diphenyl-N,N′-bis(3-methylphenyl)-(1,1′-biphenyl)-4,4′-diamine, 1,1-bis((di-4-tolylamino)phenyl)cyclohexane, N,N′-bis(4-methylphenyl)-N,N′-bis(4-ethylphenyl)-(1,1′-(3,3′-dimethyl)biphenyl)-4,4′-diamine, tetrakis-(3-methylphenyl)-N,N,N′,N′-2,5-phenylenediamine, .alpha-phenyl-4-N,N-diphenylaminostyrene, p-(diethylamino)benzaldehyde diphenylhydrazone, triphenylamine, bis(4-(N,N-diethylamino)-2-methylphenyl)(4-methylphenyl)methane, 1-phenyl-3-(p-(diethylamino)styryl)-5-(p-(diethylamino)phenyl)pyrazoline, 1,2-trans-bis(9H-carbazol-9-yl)cyclobutane, N,N,N′,N′-tetrakis(4-methylphenyl)-(1,1′-biphenyl)-4,4′-diamine, N,N′-bis(naphthalen-1-yl)-N,N′-bis-(phenyl)benzidine, and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules, such as those mentioned above, into polymers such as polystyrene and polycarbonate.

The composition of electroactive layer 104 depends on the intended function of device 100, for example, electroactive layer 104 can be a light-emitting layer that is activated by an applied voltage (such as in a light-emitting diode or light-emitting electrochemical cell), or a layer of material that responds to radiant energy and generates a signal with or without an applied bias voltage (such as in a photodetector or a solar cell). In one embodiment, electroactive layer 104 comprises an organic electroluminescent (“EL”) material, such as, for example, electroluminescent small molecule organic compounds, electroluminescent metal complexes, and electroluminescent conjugated polymers, as well as mixtures thereof. Suitable EL small molecule organic compounds include, for example, pyrene, perylene, rubrene, and coumarin, as well as derivatives thereof and mixtures thereof. Suitable EL metal complexes include, for example, metal chelated oxinoid compounds, such as tris(8-hydroxyquinolate)aluminum, cyclo-metallated iridium and platinum electroluminescent compounds, such as complexes of iridium with phenylpyridine, phenylquinoline, or phenylpyrimidine ligands as disclosed in Petrov et al., U.S. Pat. No. 6,670,645, and organometallic complexes such as those described in, for example, Published PCT Applications WO 03/008424, as well as mixtures any of such EL metal complexes. Examples of EL conjugated polymers include, but are not limited to poly(phenylenevinylenes), polyfluorenes, poly(spirobifluorenes), polythiophenes, and poly(p-phenylenes), as well as copolymers thereof and mixtures thereof.

Optional layer 105 can function as an electron injection/transport layer and/or a confinement layer. More specifically, layer 105 may promote electron mobility and reduce the likelihood of a quenching reaction if layers 104 and 106 would otherwise be in direct contact. Examples of materials suitable for optional layer 105 include, for example, metal chelated oxinoid compounds, such as bis(2-methyl-8-quinolinolato)(para-phenyl-phenolato)aluminum(III) and tris(8-hydroxyquinolato)aluminum, tetrakis(8-hydroxyquinolinato)zirconium, azole compounds such as 2-(4-biphenylyl)-5-(4-t-butylphenyl)-1,3,4-oxadiazole, 3-(4-biphenylyl)-4-phenyl-5-(4-t-butylphenyl)-1,2,4-triazole, and 1,3,5-tri(phenyl-2-benzimidazole)benzene, quinoxaline derivatives such as 2,3-bis(4-fluorophenyl)quinoxaline, phenanthroline derivatives such as 9,10-diphenylphenanthroline and 2,9-dimethyl-4,7-diphenyl-1,10-phenanthroline, and as well as mixtures thereof. Alternatively, optional layer 105 may comprise an inorganic material, such as, for example, BaO, LiF, Li₂O.

Cathode layer 106 can be any metal or nonmetal having a lower work function than anode layer 101. Materials suitable for use as cathode layer 106 are known in the art and include, for example, alkali metals of Group 1, such as Li, Na, K, Rb, and Cs, Group 2 metals, such as, Mg, Ca, Ba, Group 12 metals, lanthanides such as Ce, Sm, and Eu, and actinides, as well as aluminum, indium, yttrium, and combinations of any such materials. Specific non-limiting examples of materials suitable for cathode layer 106 include, but are not limited to, Barium, Lithium, Cerium, Cesium, Europium, Rubidium, Yttrium, Magnesium, Samarium, and alloys and combinations thereof. Cathode layer 106 is typically formed by a chemical or physical vapor deposition process. In some embodiments, the cathode layer will be patterned, as discussed above in reference to the anode layer 101.

In one embodiment, an encapsulation layer (not shown) is deposited over cathode layer 106 to prevent entry of undesirable components, such as water and oxygen, into device 100. Such components can have a deleterious effect on electroactive layer 104. In one embodiment, the encapsulation layer is a barrier layer or film. In one embodiment, the encapsulation layer is a glass lid.

Though not shown in FIG. 1, it is understood that device 100 may comprise additional layers. Other layers that are known in the art or otherwise may be used. In addition, any of the above-described layers may comprise two or more sub-layers or may form a laminar structure. Alternatively, some or all of anode layer 101, buffer layer 102, hole transport layer 103, electron transport layer 105, cathode layer 106, and any additional layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

The various layers of the electronic device can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing. Other layers in the device can be made of any materials which are known to be useful in such layers upon consideration of the function to be served by such layers.

A person skilled in the art would recognize that the various layers of the electronic device will depend on the desired application. For example, as is known in the art, the location of the electron-hole recombination zone in the device, and thus the emission spectrum of the device, can be affected by the relative thickness of each layer. The appropriate ratio of layer thicknesses will depend on the exact nature of the device and the materials used.

In an embodiment, the electronic device in accordance with the present invention comprises:
(a) an anode or combined anode and buffer layer 101,
(b) a cathode layer 106,
(c) an electroactive layer 104, disposed between anode layer 101 and cathode layer 106,
(d) optionally, a buffer layer 102, typically disposed between anode layer 101 and electroactive layer 104,
(e) optionally, a hole transport layer 105, typically disposed between anode layer 101 and electroactive layer 104, or if buffer layer 102 is present, between buffer layer 102 and electroactive layer 104, and
(f) optionally an electron injection layer 105, typically disposed between electroactive layer 104 and cathode layer 106,
   wherein at least one of the layers of the device, typically at least one of the anode or combined anode and buffer layer 101 and, if present, buffer layer 102 comprises metal nanoparticles synthesized or modified, or both, by the methods described herein.

In one embodiment, the electronic device of the present invention is a device for converting radiation into electrical energy, and comprises an anode 101, a cathode layer 106, an electroactive layer 104 comprising a material that is capable of converting radiation into electrical energy, disposed between the anode layer 101 layer and the cathode layer 106, and optionally further comprising a buffer layer 102, a hole transport layer 103, and/or an electron injection layer 105, wherein at least one of the layers comprises metal nanoparticles synthesized or modified, or both, by the methods described herein.

In operation of an embodiment of device 100, such as device for converting radiation into electrical energy, device 100 is exposed to radiation impinges on electroactive layer 104, and is converted into a flow of electrical current across the layers of the device.

The present invention also relates to a catalyst comprising the metal nanoparticles synthesized or modified, or both, by the methods described herein, and, optionally, a support.

The optional support is selected such that it is in a suitably shaped form, is chemically and thermally stable under the conditions of catalyst synthesis and under reaction conditions of catalyst use, is mechanically stable, does not deteriorate the performance of the catalyst, does not interfere with the catalyzed reaction, and enables anchoring of the metal nanoparticles. Any support which meets these requirements may be used.

Suitable supports include, but are not limited to, activated carbon, metal hydroxides, metal oxides, mixed metal oxides, oxides of aluminum, oxides of silicon, and combinations thereof. Exemplary of metal hydroxides, metal oxides and mixed metal oxides are hydroxides and oxides comprising one or more metals from the Group 2 elements (i.e., Be, Mg, Ca, Sr, Ba, Ra), and the transition metals of Groups 4-12. Typically, these are present in crystalline form.

Some non-limiting, specific examples of suitable supports include, but are not limited to, Be(OH)₂, Mg(OH)₂, TiO₂, TiO₂ (rutile), TiO₂ (anatase), Ti—SiO₂, ZrO₂, CeO₂ V₂O₅, Cr₂O₃, MnO₂, Mn₂O₃, Fe₂O₃, RuO₂, Co₃O₄, NiO, NiFe₂O₄, PdO, PtO₂, CuO, Ag₂O, ZnO, Al₂O₃, SiO₂, and combinations thereof.

The procedure for coating the active metal nanoparticles on the support can be performed by methods known to the skilled artisan and described in the literature.

The present invention is further illustrated by the following non-limiting examples.

### Example 1. Synthesis of Gold Nanoparticles According to the Present Invention

At room temperature, 50 mL of an aqueous solution of HAuCl₄ at 0.5 mM (made from a ˜0.2 M HAuCl₄ stock solution) was placed in a 100 mL Erlenmeyer or a round bottom flask. Under vigorous stirring, 0.5 mL of aqueous ascorbic acid (AA) solution at 0.1 M was introduced. The HAuCl₄ and ascorbic acid solutions were both free of stabilizing agent and free of seed particles. The final concentration of ascorbic acid was 1 mM. The HAuCl₄:AA ratio, denoted “[Au]:[AA]”, was 1:2. The combined reaction mixture was stirred vigorously for 30 seconds, after which the reaction mixture was gently stirred for 1 hour.

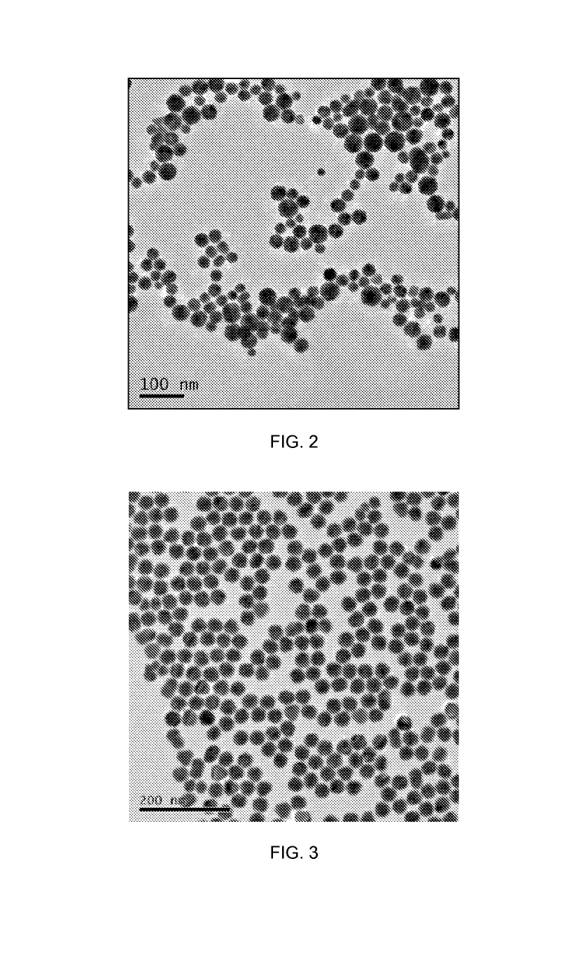

The metal nanoparticles formed, designated “Au@AA”, have a diameter of 31±7 nm and 23% polydispersity. A transmission electron micrograph (TEM) is shown in FIG. 2.

### Comparative Example 1. Synthesis of Gold Nanoparticles in the Presence of Stabilizing Agent

For comparison, metal nanoparticles were synthesized in the presence of stabilizing agent according to a published procedure (Rodriguez-Fernandez et al. Langmuir 22, 7007, 2006). In addition to ascorbic acid, synthesis according to the published procedure required the addition of cetyltrimethylammonium bromide (CTAB) as a stabilizing agent and heating at 35° C. The metal nanoparticles formed were designated “Au@CTAB” nanoparticles. The “Au@CTAB” nanoparticles have a diameter of 33±2 nm and 5% polydispersity. The TEM image of the “Au@CTAB” nanoparticles is shown in FIG. 3.

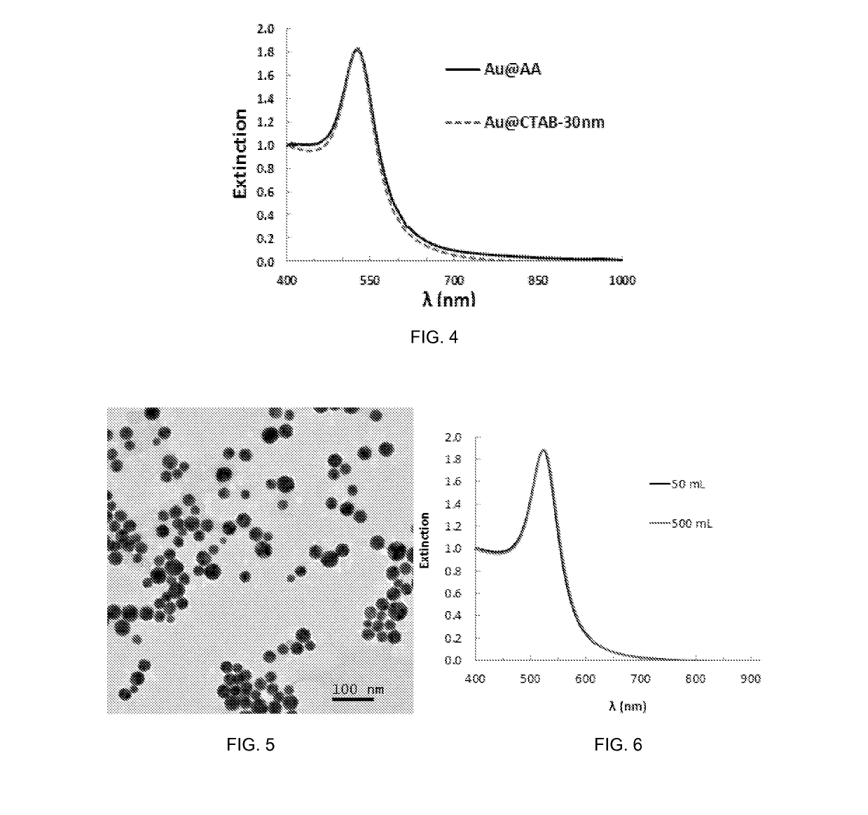

The inventive “Au@AA” nanoparticles were compared to the “Au@CTAB” nanoparticles formed by a published procedure. The extinction curves for the inventive “Au@AA” nanoparticles and the “Au@CTAB” nanoparticles are shown in FIG. 4. The extinction curve presents a maximum around 528 nm which is consistent with the size obtained by TEM. The plasmonic response of the inventive Au@AA nanoparticles is similar to the response of the Au@CTAB nanoparticles, whose size polydispersity is known to be small.

### Example 2

Gold nanoparticles were synthesized according to the procedure described in Example 1. However, the volumes of the HAuCl₄ and ascorbic acid solutions were increased 10-fold.

The metal nanoparticles synthesized were identical to the nanoparticles made according to Example 1. The TEM image of the nanoparticles made according to Example 2 is shown in FIG. 5, and a comparison of the extinction curves of the nanoparticles made according to Example 1 and 2 are shown in FIG. 6.

### Example 3

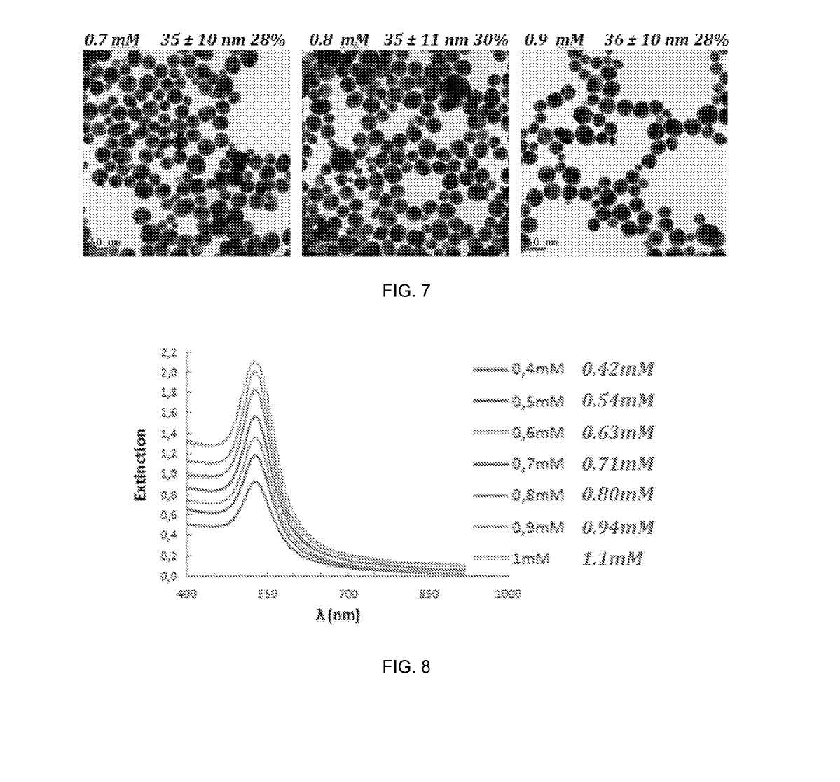

Metal nanoparticles were synthesized according to the procedure described in Example 1. The ratio [Au]:[AA] was maintained at 1:2, but the concentrations of each of the HAuCl₄ and AA solutions were varied while maintaining the ratio [Au]:[AA]=1:2. The HAuCl₄ concentration was varied from 0.4 mM to 1 mM. TEM images of the metal nanoparticles made at various concentrations of HAuCl₄ and AA are shown in FIG. 7. 0.7 mM HAuCl₄ resulted in nanoparticles having a diameter of 35±10 nm and 28% polydispersity, 0.8 mM HAuCl₄ resulted in nanoparticles having a diameter of 35±11 nm and 30% polydispersity, and 0.9 mM HAuCl₄ resulted in nanoparticles having a diameter of 36±10 nm and 28% polydispersity.

The extinction curves of the metal nanoparticles made by varying the concentrations of HAuCl₄ and AA are shown in FIG. 8. The concentrations in the left column of the legend refer to HAuCl₄ concentrations, and the concentrations in the right column in the legend refer to nanoparticle concentration.

Generally, by increasing the metal precursor compound and the ascorbic acid concentrations, the nanoparticles obtained have the same properties as those made according to Example 1.

### Example 4

Metal nanoparticles were synthesized according to the procedure described in Example 1. However, only the concentration of the HAuCl₄ solution varied. The HAuCl₄ concentration was varied from 0.5 mM to 1 mM. The concentration of AA in the ascorbic acid solution was maintained (0.1 M) such that introduction of 0.5 mL of AA solution resulted in a final concentration of 1 mM in the reaction mixture. The results are summarized in the Table 1.

TABLE 1

| [HAuCI4] | [AA] | Diameter | % |
|---|---|---|---|
| (mM) | (mM) | (nm) | polydispersity |
| 0.5 | 1 | 25 ± 8 | 32 |
| 0.6 | 1 | 32 ± 8 | 25 |
| 0.7 | 1 | 35 ± 7 | 22 |
| 0.8 | 1 | 42 ± 12 | 28 |
| 0.9 | 1 | 45 ± 13 | 29 |
| 1 | 1 | 76 ± 23 | 30 |

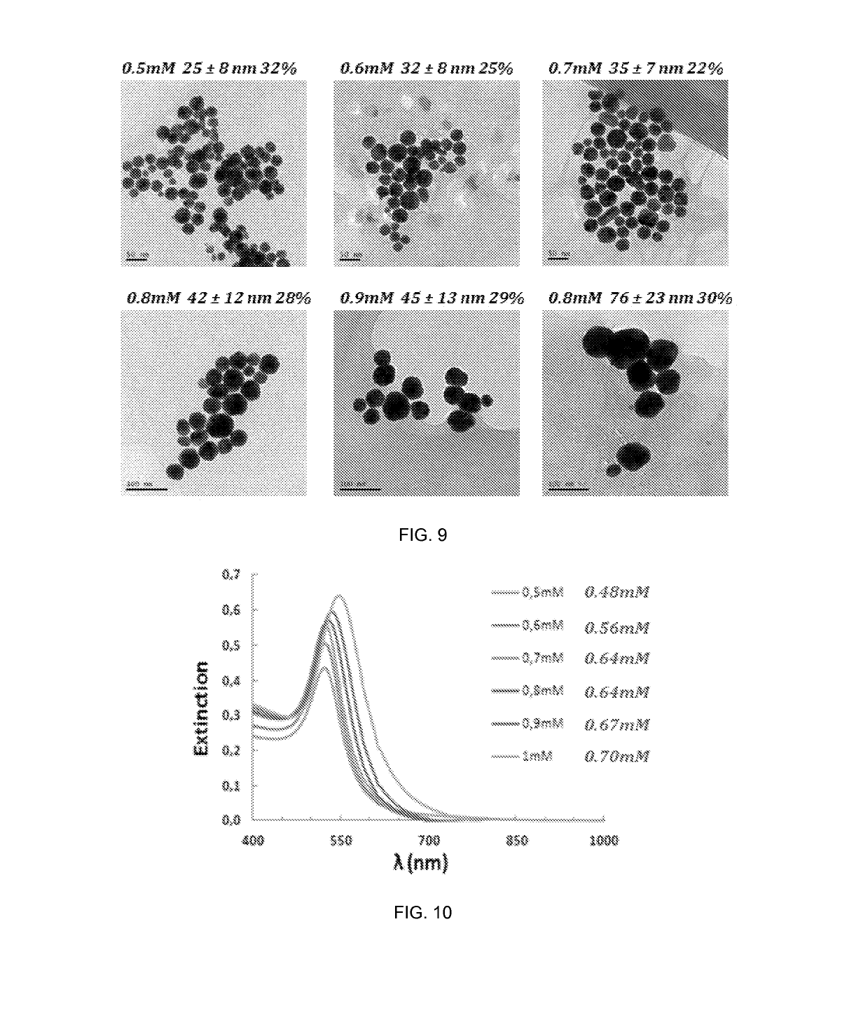

TEM images of the metal nanoparticles made at various concentrations of HAuCl₄ are shown in FIG. 9.

The extinction curves of the metal nanoparticles made by varying the concentrations of HAuCl₄ are shown in FIG. 10. The concentrations in the left column of the legend refer to HAuCl₄ concentrations, and the concentrations in the right column in the legend refer to nanoparticle concentration.

An AA concentration of 1 mM is not sufficient to reduce all the gold salt above a concentration of 0.6 mM. It is believed that this lack results in an increase in the size of the nanoparticles. Indeed, as seen in Example 3, when the amount of AA is sufficient to reduce all the gold salt, the nanoparticles obtained were the same regardless of initial gold salt concentration. The size polydispersity remains mostly unchanged when the size increases.

### Example 5

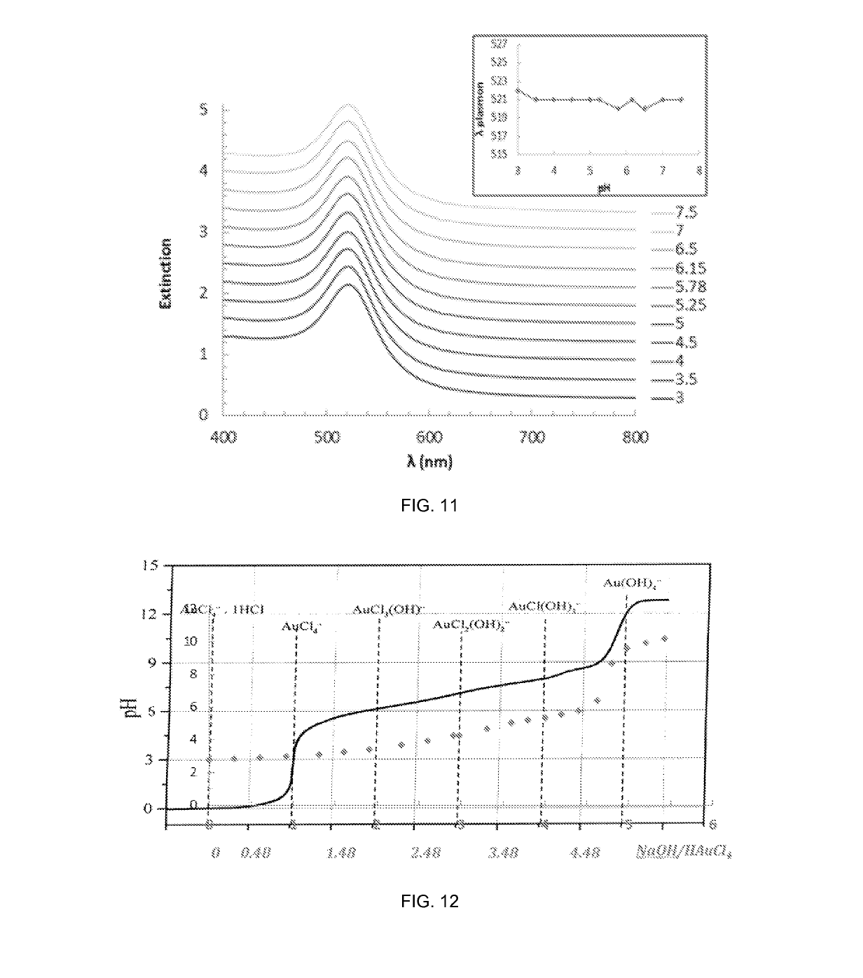

The pH of the reaction mixture after the completion of the reaction was altered by the addition of a base. In this case, sodium hydroxide (0.1 M aqueous solution) was added to the reaction mixture and the extinction curves of the metal nanoparticles were obtained after each addition. Typically, the pH of the reaction mixture at the end of the reaction is about 2.7. The pH may be increased by the addition of a base to at least 7.5 while maintaining stability of the metal nanoparticles, as demonstrated by results shown in FIG. 11.

### Example 6

The effect of the pH of the HAuCl₄ solution on the morphology of the nanoparticles formed was investigated.

It is known that depending of the pH, the complex HAuCl₄ species change due to an equilibrium represented by Equation 1:

HAuCl₄₋ₓ(OH)ₓ+HO⁻ [symbol] HAuCl₄₋₍ₓ₊₁₎(OH)ₓ₊₁+Cl⁻ (Equation 1)

FIG. 12 shows a superposition of the titration curve of a HAuCl₄ solution at 1.64 M (D. V. Goia, Colloids and Surfaces A: Physicochem. Eng. Aspects 146, 1999, 139) and a titration curve of a HAuCl₄ solution at 0.5 mM according to the present invention, represented by diamond-shaped and square-shaped points. Each diamond-shaped or square-shaped point in FIG. 12 represents a 50 mL solution of HAuCl₄ with a varying amount of NaOH. The numbers below the graph represent molar ratios of NaOH/HAuCl₄.

The difference at V_{NaOH}=0 mL can be explain by the difference of hydronium (H+) concentration. Indeed for [H+]=1.64 M, pH=−0.2 and for [H+]=0.5 mM, pH=3. Above NaOH/HAuCl₄=1, the difference in pH may be explained by the difference of concentration of the different species, as in dilute solution, the reaction rate is really slow and the equilibrium Equation 1 can be shifted.

Since each point in FIG. 12 represents a 50 mL solution of HAuCl₄ with a varying amount of NaOH, gold nanoparticles were made from these solutions by adding 0.5 mL of ascorbic acid at 0.1 M as in Example 1 to each 50-mL solution of HAuCl₄.

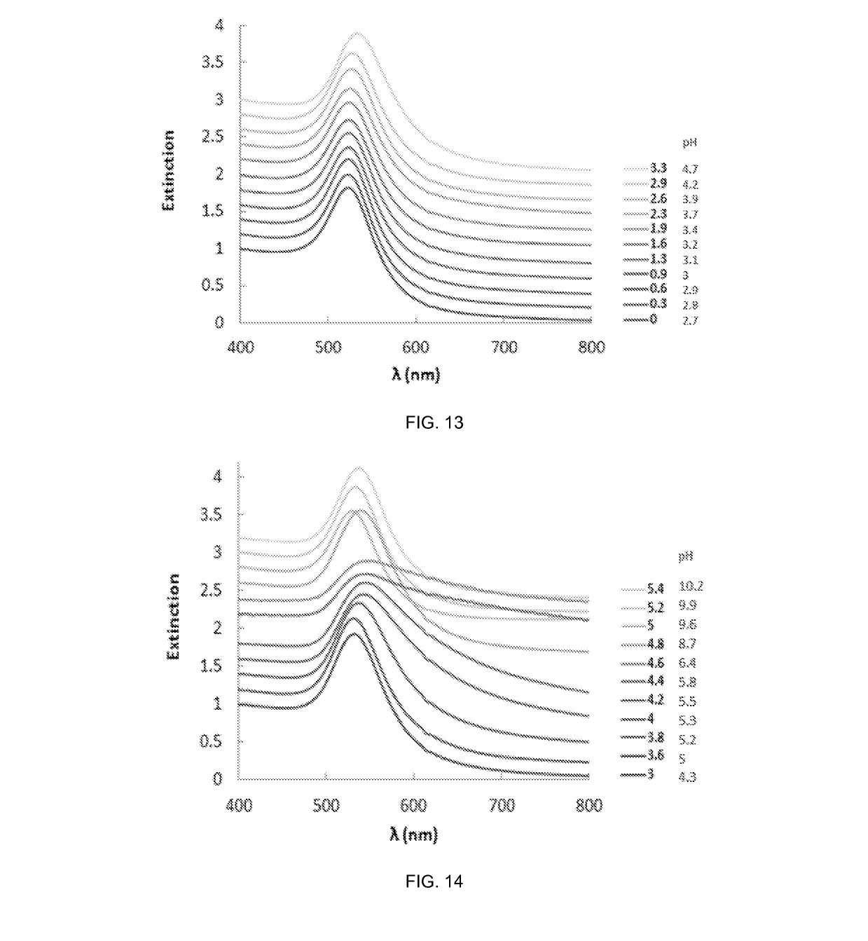

FIG. 13 and FIG. 14 each show the extinction spectra of the metal nanoparticles made with varying ratios of NaOH/HAuCl₄. The left column in the legends represent molar ratio of NaOH/HAuCl₄ and the right column in the legends represent the corresponding pH.

The HAuCl₄ complex form believed to be present as a function of the ratio NaOH/HAuCl₄ is presented in the results. Hereinafter, the ratio NaOH/HAuCl₄ will be referred to as “R”.

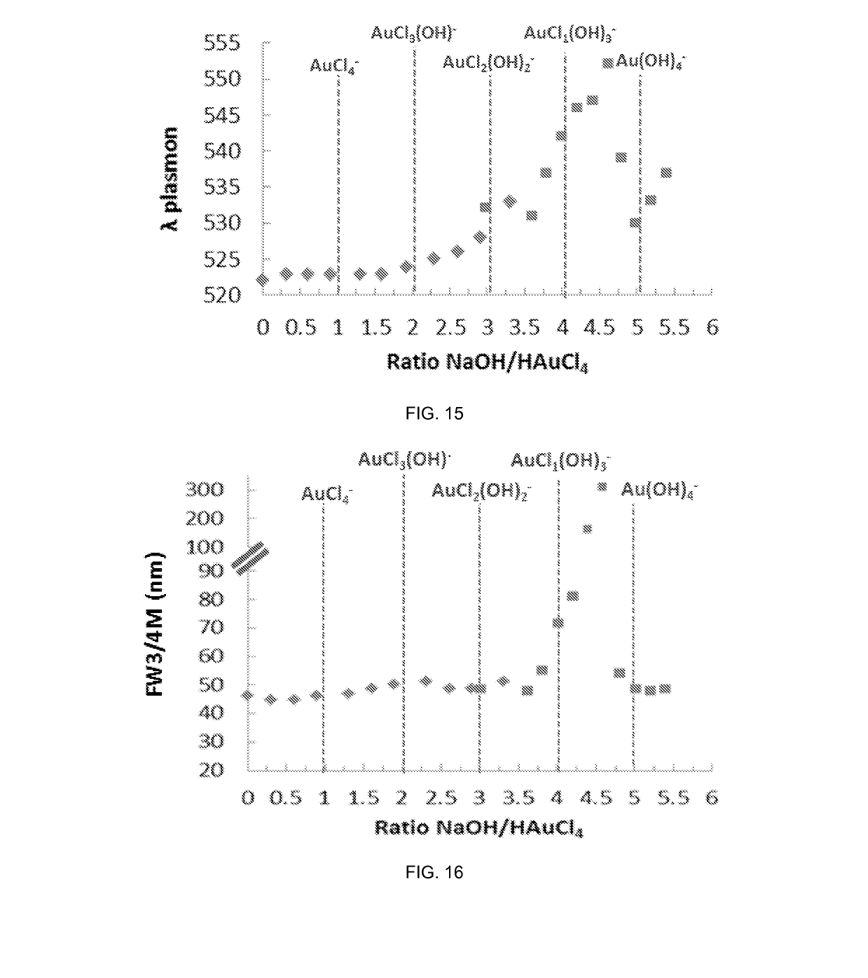

FIG. 15 shows the evolution of the position of the plasmon peak when the amount of NaOH is increased. When R is smaller than 2, the plasmon peaks appears at similar wavelengths so the nanoparticles are expected to have a similar diameter. For 2<R<4.5, the plasmonic resonance is red-shifted (i.e., shifted towards longer wavelength), reflecting the formation of bigger nanoparticles. Above R=4.6, a significant decrease in the resonance wavelength, certainly associated with the formation of smaller particles, can be observed. This change is followed by a second increase of the plasmonic peak position.

FIG. 16 shows the evolution of the full width at ¾ of the maximum (FW3/4M) of the plasmon peak as the amount of NaOH is increased. Due to the presence of the interband transition it is difficult to show the full width at half of the maximum (FWHM) so the value at ¾ of the maximum is used. For a given size, the broader the peak, the more polydisperse the particles are. When the particle's size increases, the plasmonic peak tends to be broader. At R<3, the peak width increases slowly. From 3 to 4.6, the peak widths become really broad and can be clearly seen on the UV-Vis Spectrum. This excessive broadening is due to aggregation or high polydispersity. For R>4.6, the peak width reduces to about 45 nm. The position being more red-shifted than 0<R<3, the polydispersity is expected to be smaller.

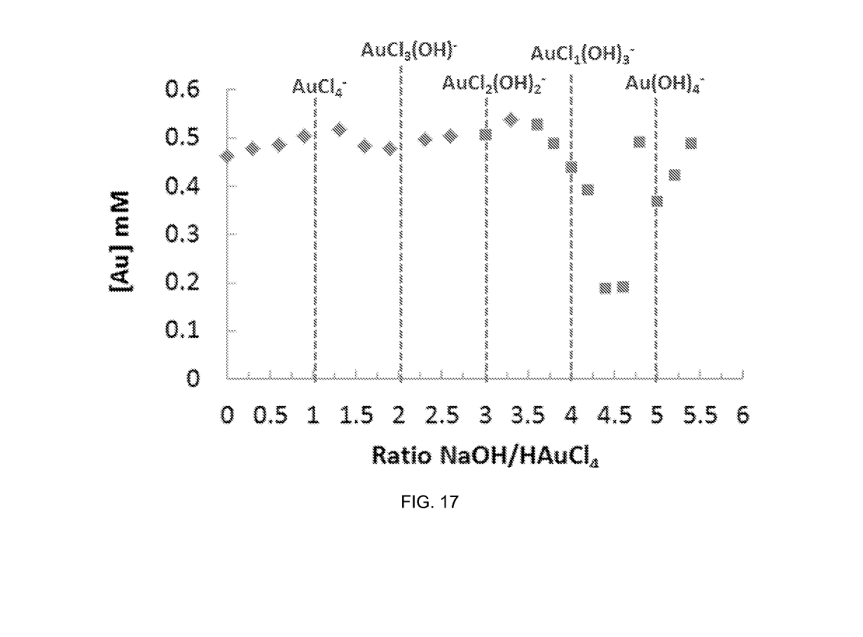

FIG. 17 shows the concentration of metal nanoparticle concentration as a function of R. For R>3.5, incomplete reduction of the HAuCl₄ (initial concentration: 0.5 mM) can be observed. The reduced gold nanoparticle concentration was determined by the value of the absorbance at 400 nm.

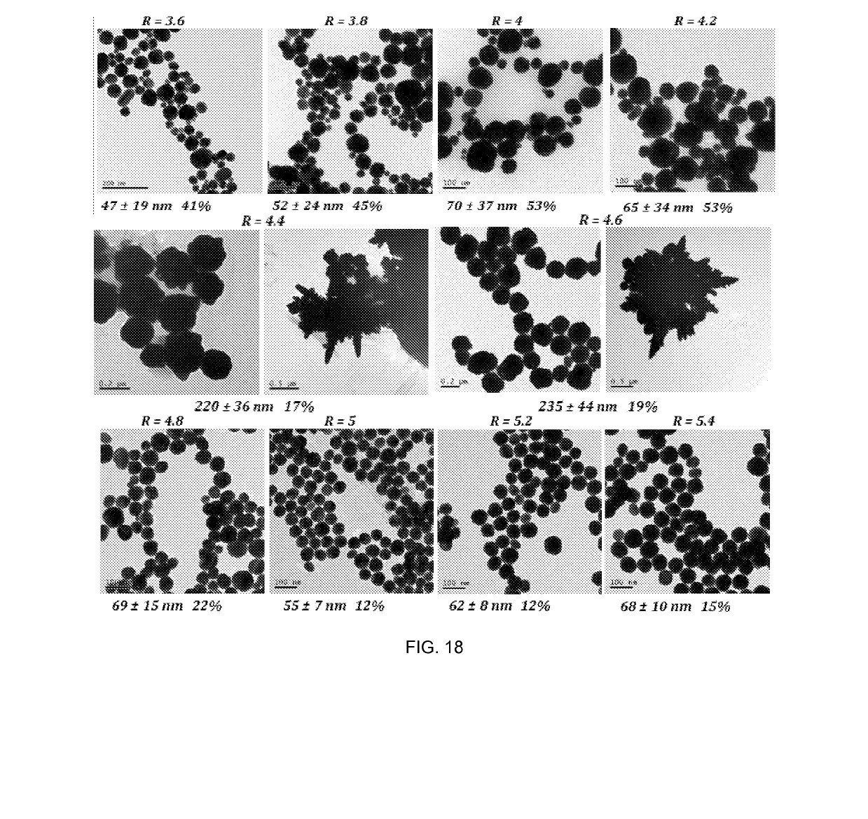

FIG. 18 shows the TEM images of metal nanoparticles formed with R greater than 3. The nanoparticle diameter and dispersity are summarized in Table 2.

TABLE 2

| R | Diameter (nm) | % polydispersity |
|---|---|---|
| 3.6 | 47 ± 19 | 41 |
| 3.8 | 52 ± 24 | 45 |
| 4 | 70 ± 37 | 53 |
| 4.2 | 65 ± 34 | 53 |
| 4.4 | 220 ± 36 | 17 |
| 4.6 | 235 ± 44 | 19 |
| 4.8 | 69 ± 15 | 22 |
| 5 | 55 ± 7 | 12 |
| 5.2 | 62 ± 8 | 12 |
| 5.4 | 68 ± 10 | 15 |

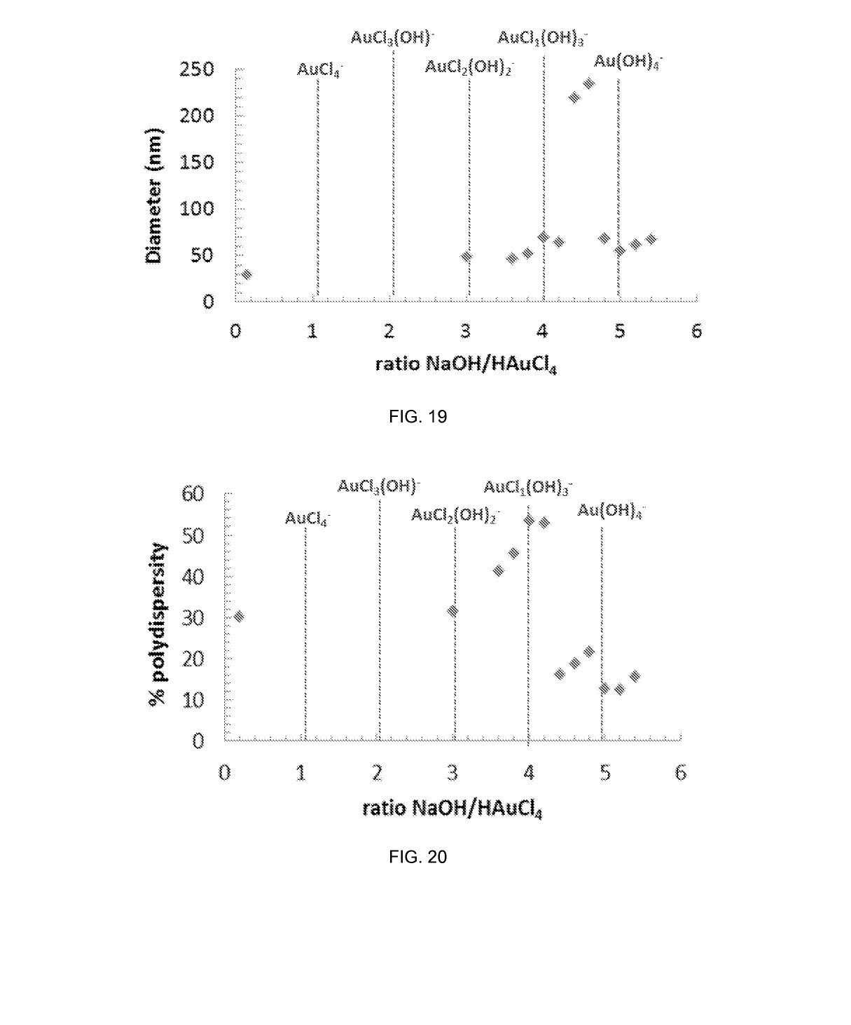

The TEM images are consistent with the UV-Vis spectra. Above R=3, there is an increase of the particles size and their polydispersity. There two extreme values (R=4.6 and 4.8) that show a mixture of really large nanoparticles and dendritic shaped agglomerates. For R>5, the nanoparticles are bigger and more monodispersed than those made according Example 1. FIG. 19 and FIG. 20 show the diameter and % polydispersity, respectively, as functions of R.

### Example 7. Synthesis of Silver Nanoparticles According to the Present Invention

9 mL of ascorbic acid solution (4 mM ascorbic acid in water) was placed in a 20-mL beaker at room temperature. 1 mL of NaOH solution (0.1 M NaOH in water) was then introduced to the ascorbic acid solution. The pH of the resulting mixture was about 9. After the pH stabilized, 0.1 mL of an aqueous solution of AgNO₃ (0.1 M AgNO₃ in water) was added under a vigorous stirring (final AgNO₃ concentration: 1 mM). After 30 s of vigorous stirring, the reaction mixture was gently stirred for 1 hour.

The AgNO₃ and ascorbic acid solutions, before and after addition of NaOH, were both free of stabilizing agent and free of seed particles.

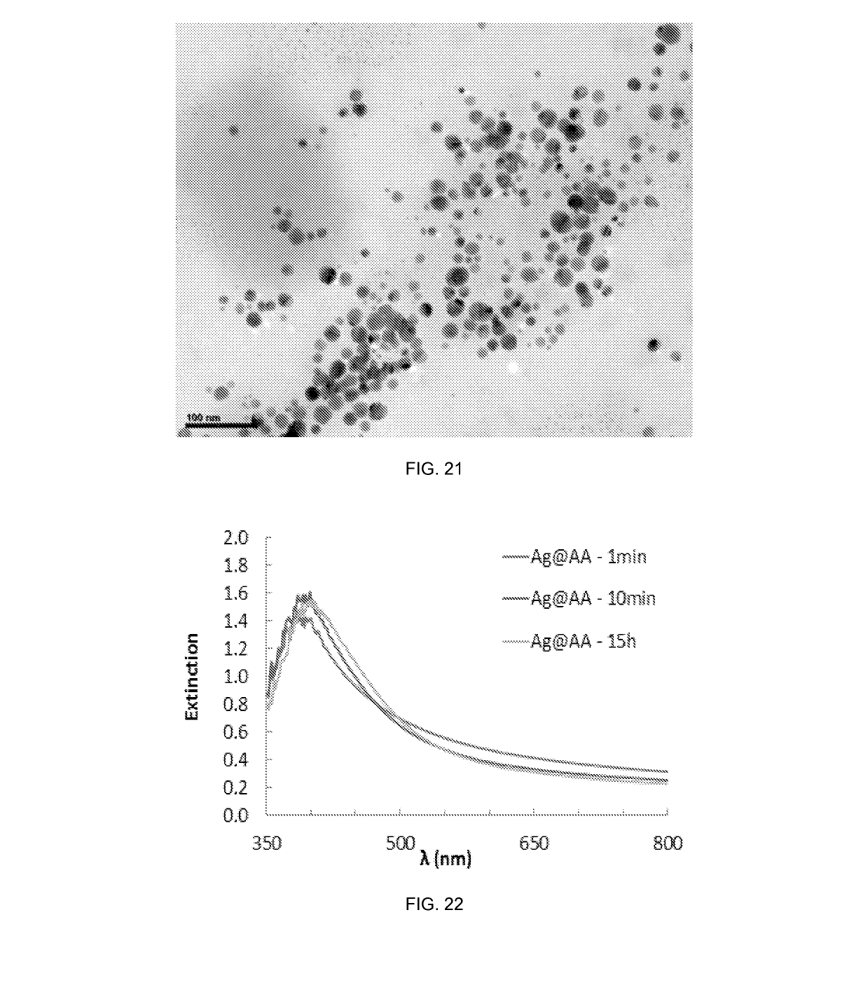

The silver nanoparticles formed, designated “Ag@AA”, have a diameter of 15±6 nm and 39% polydispersity. A TEM image of the silver nanoparticles is shown in FIG. 21 and the extinction curve is shown in FIG. 22.

### Example 8. Surface Modification of Gold Nanoparticles According to the Present Invention

The metal nanoparticles made according to Example 1 were modified by the following general process.

A surfactant solution was added to a suspension of the metal nanoparticles, typically the reaction mixture, or a portion thereof, containing the metal nanoparticles. The combined mixture was centrifuged, and the resulting supernatant was removed. The process was optionally repeated by adding more of the same surfactant solution, centrifuging the mixture, and then removing the supernatant. This step may be repeated as many times as desired to ensure complete removal of any ascorbic acid that may remain.

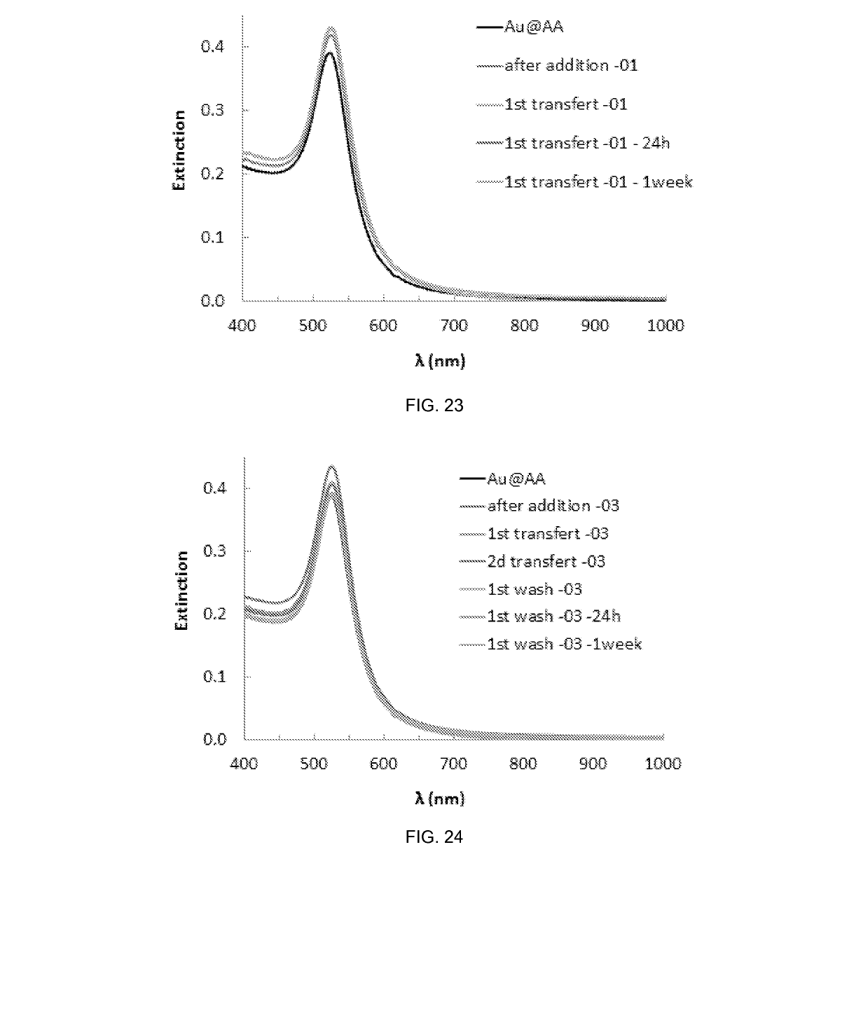

The surfactants used and the extinction curves of the corresponding surface-modified metal nanoparticles are represented in Table 3 below. In FIG. 23-32, “1^{st} transfer” refers to adding the surfactant solution to a suspension of the metal nanoparticles before the first centrifugation, and “2d transfer” refers to adding the surfactant solution to the suspension of the metal nanoparticles after centrifugation and removal of supernatant. In FIG. 23-32, metal nanoparticles made according to Example 1, designated therein as “Au@AA”, are used a reference.

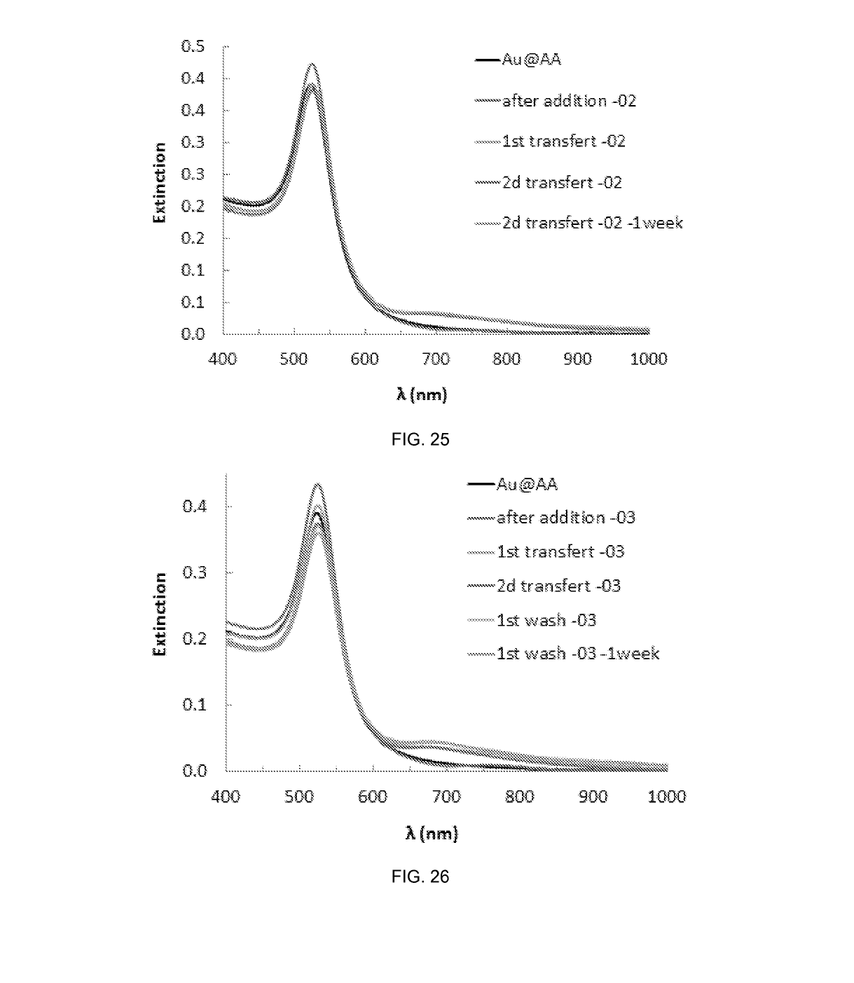

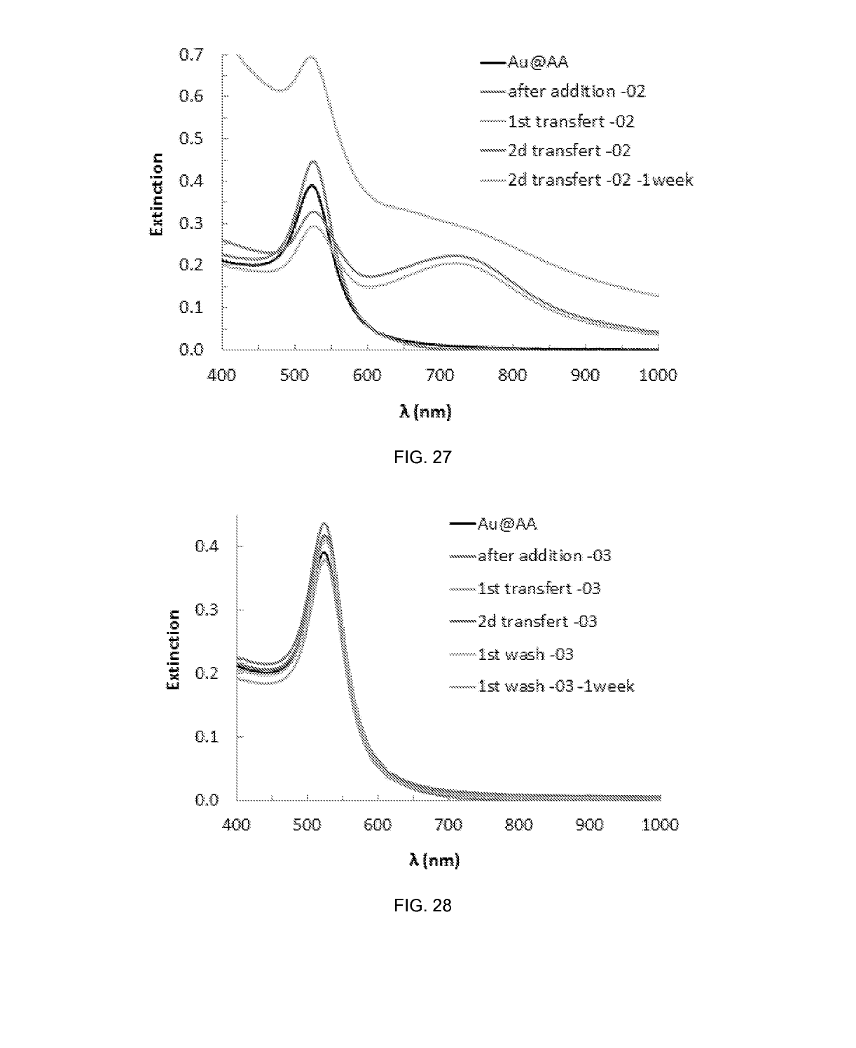

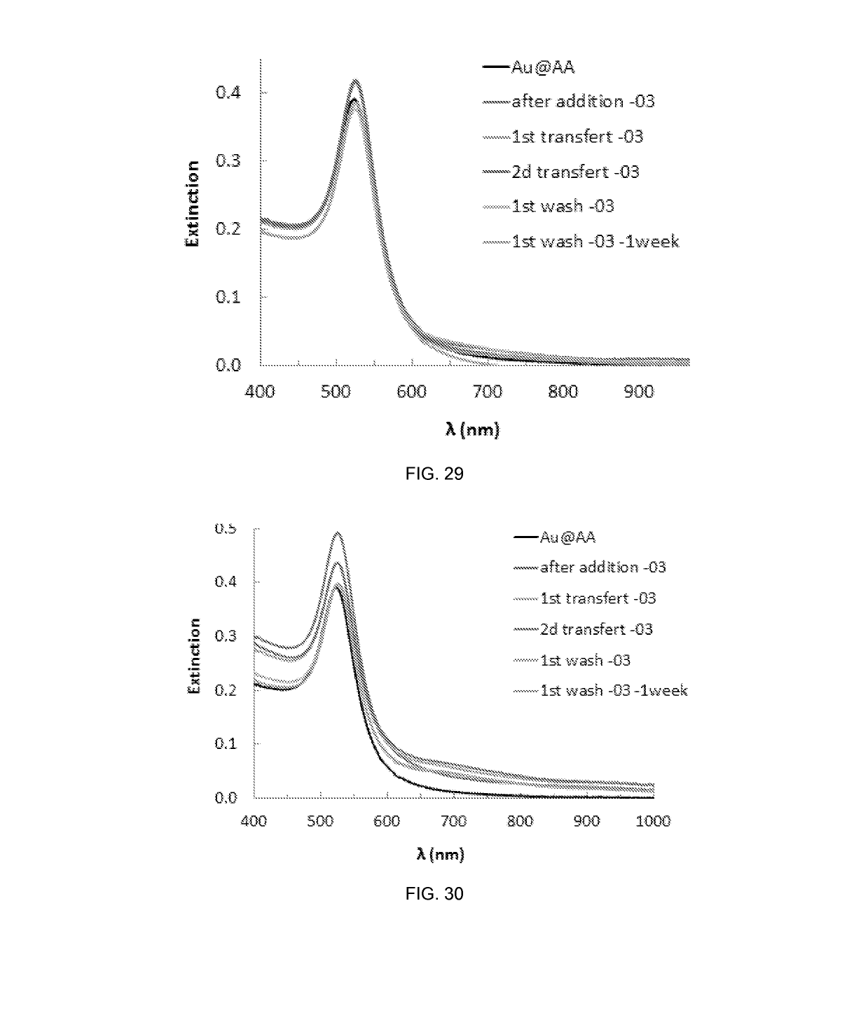

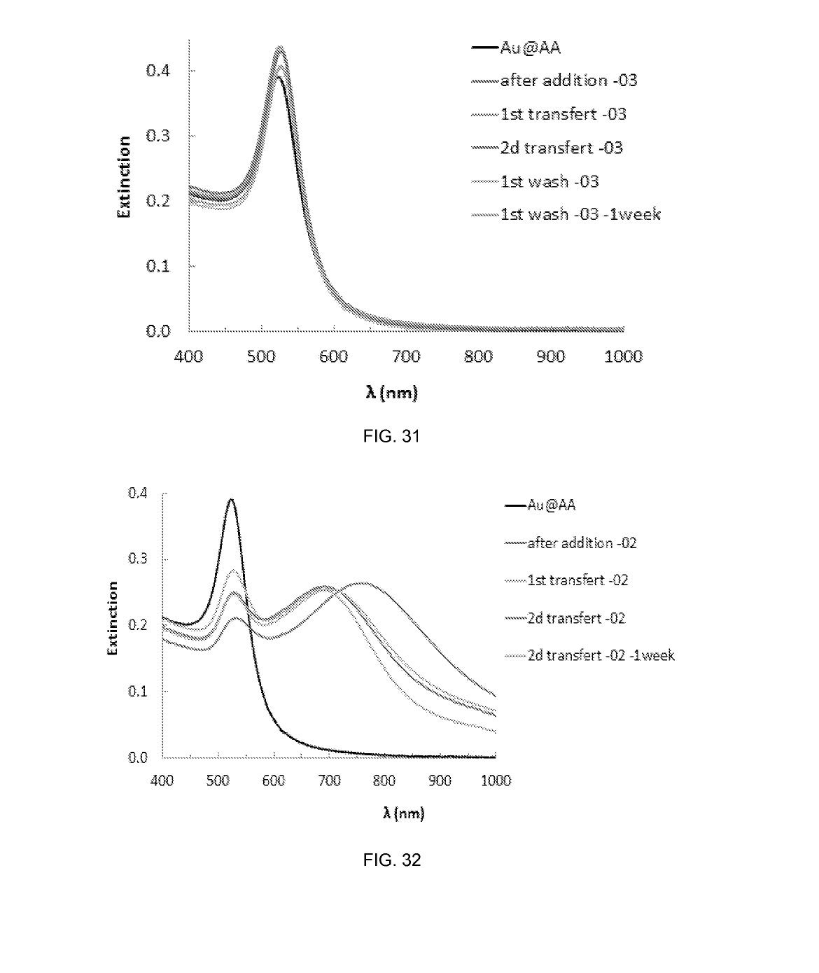

TABLE 3

| Surfactant | Extinction curve |
|---|---|
| Alkyl thio ethoxylates (ALCODET ®) | FIG. 23 |
| Polysorbate monoleate (ALKAMULS ® | FIG. 24 |
| PSMO) | |
| EO/PO block copolymer (ANTAROX ® | FIG. 25 |
| L-64) | |
| ANTAROX ® BL-750 | FIG. 26 |
| ethoxylated propoxylated C₁₀-C₁₆ | FIG. 27 |
| alcohols (ANTAROX ® RA-40) | |
| 2-(methyloleoylamino)ethane-1-sulfonate | FIG. 28 |
| (GEROPON ® T77) | |
| ethoxylated nonylphenol (IGEPAL ® | FIG. 29 |
| CO-630) | |
| ethoxylated dinonylphenol/nonylphenol | FIG. 30 |
| (IGEPAL ® DM-530) | |
| diphenyl oxide sulfonate (RHODACAL ® | FIG. 31 |
| DSB) | |
| caprylamphodipropionate (MIRANOL ® | FIG. 32 |
| JBS) | |

FIG. 23-32 present the extinction spectra of the different surfactants used. For some of them, the curves are almost unchanged which shows that the surfactant added does protect the Au nanoparticles from aggregation and are, thus, on their surface.

In some of the extinction curves, two peaks are observed. It is believed that one may correspond to single particles and the second may be associated with the formation of multimers, for example.

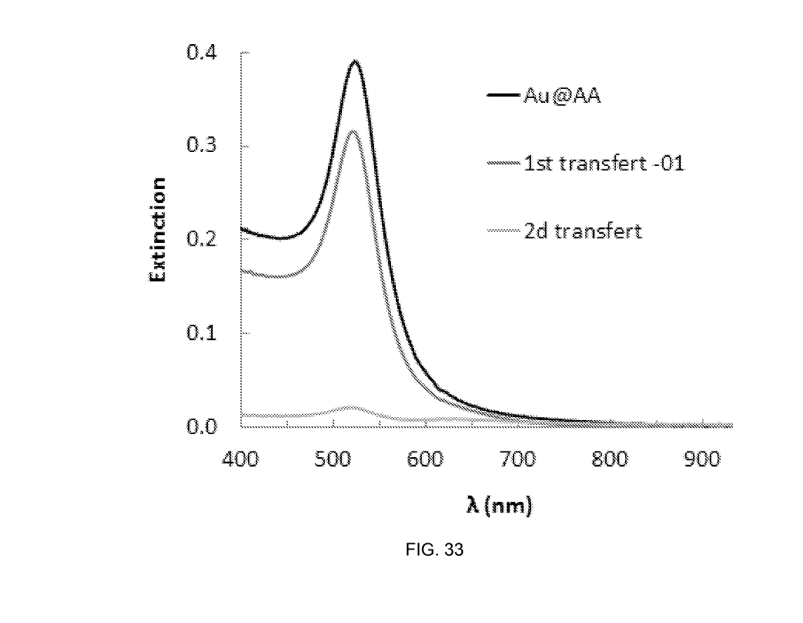

When the surface modification process was done with ascorbic acid instead of surfactant, aggregation of the nanoparticles under centrifugation was observed. It is believed that ascorbic acid does not sufficiently protect the nanoparticles. This result is shown in FIG. 33.

### Example 9

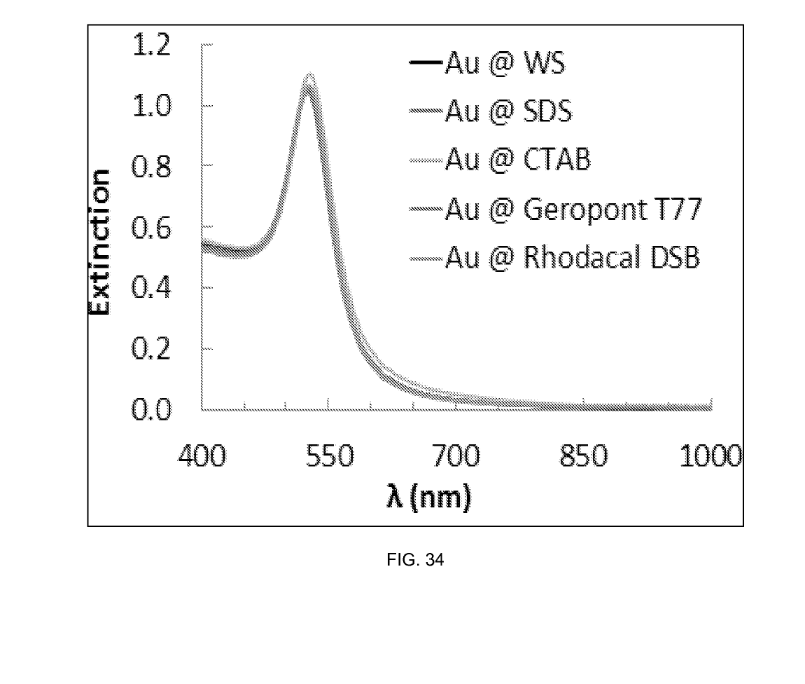

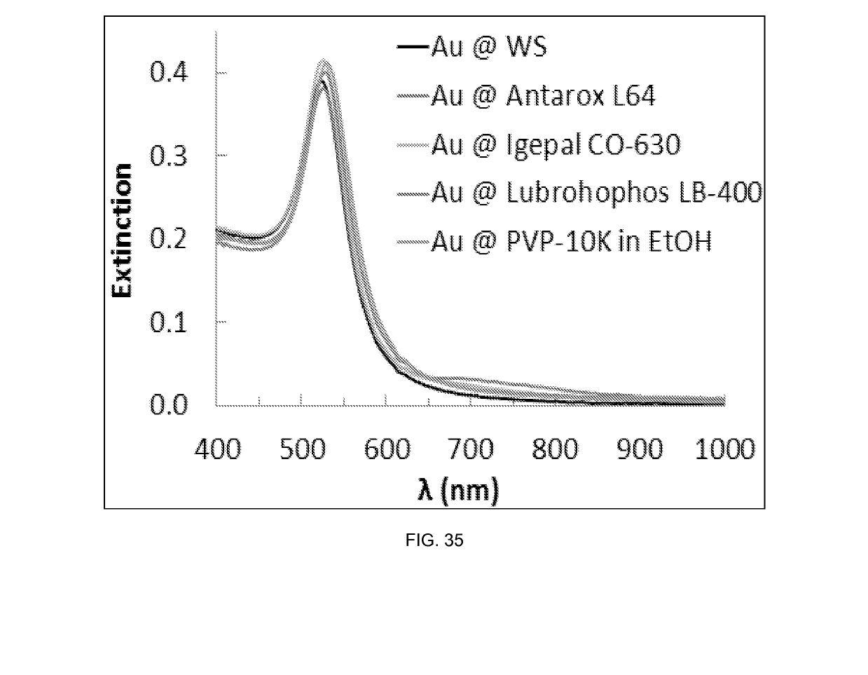

Various surfactants were compared. Metal nanoparticles made according to Example 1 were modified according to the procedure described in Example 8. Table 4 compares various cationic and anionic surfactants and Table 5 compares various nonionic surfactants and polymers. In FIG. 34 and FIG. 35, metal nanoparticles made according to Example 1, designated therein as “Au@WS”, are used a reference.

TABLE 4
Cationic and anionic surfactants

| Surfactant | Extinction curve |
|---|---|
| Sodium dodecylsulfate (SDS) | FIG. 34 |
| cetyltrimethylammonium bromide (CTAB) | |
| 2-(methyloleoylamino)ethane-1-sulfonate | |
| (GEROPON ® T77) | |
| diphenyl oxide sulfonate (RHODACAL ® | |
| DSB) | |

TABLE 5
Nonionic surfactants and polymers

| Surfactant | Extinction curve |
|---|---|
| EO/PO block copolymer (ANTAROX ® L-64) | FIG. 35 |
| ethoxylated nonylphenol (IGEPAL ® CO-630) | |
| polyoxyethylene octadecenyl ether | |
| phosphates (LUBRHOPHOS ® LB-400) | |
| Poly(vinylpyrrolidone) (PVP-10K in ethanol) | |

In FIGS. 34 and 35, the extinction curves are almost unchanged which shows that the surfactants used protect the Au nanoparticles from aggregation.

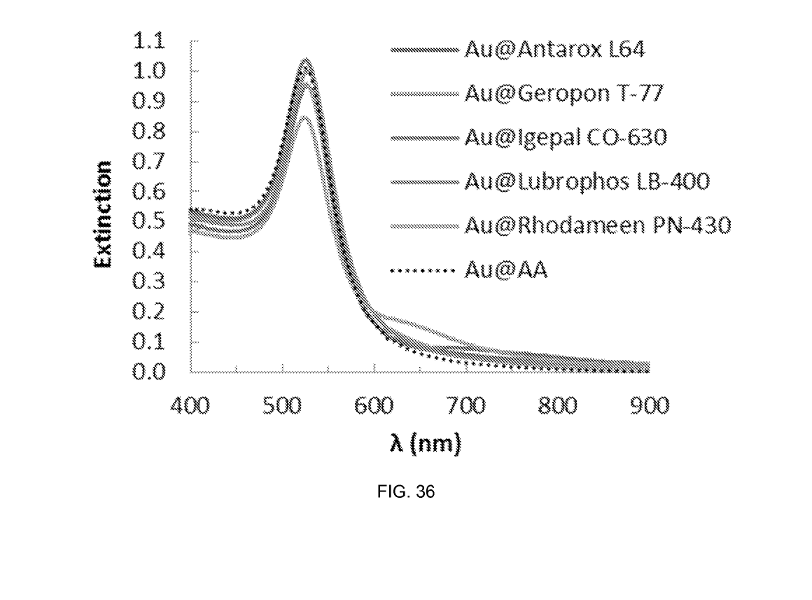

FIG. 36 shows the extinction curves of nanoparticles modified by some surfactants listed in Tables 4 and 5 along with the extinction curve of nanoparticles modified by cationic ethoxylated fatty amine, ethoxylated oleyl amine (RHODAMEEN® PN-430).

### Example 10

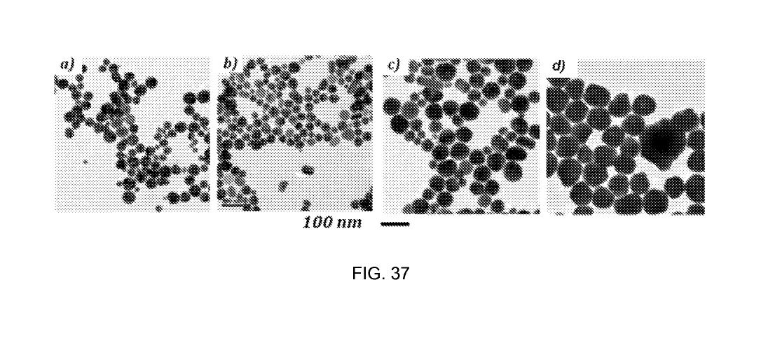

Gold nanoparticles were made according to the method used in Example 6. The effect of R less than 3.6 and R greater than 5.4 on the diameters and polydispersity of the resulting nanoparticles are summarized in Table 6 below. FIG. 37 shows the TEM images of nanoparticles formed with a) R=0, b) R=1.6, c) R=2.9, and d) R=6.4.

TABLE 6

| | R = [NaOH]/[HAuCl₄] | | | |
|---|---|---|---|---|
| | 0 | 1.6 | 2.9 | 6.4 |
| Diameter (nm) | 29 | 30 | 48 | 82 |
| Polydispersity (%) | 28 | 30 | 41 | 24 |
| FIGURE | 37a | 37b | 37c | 37d |

### Example 11

The effect of the addition of base to the ascorbic acid (AA) solution prior to its introduction to the HAuCl₄ solution to form the inventive nanoparticles was investigated.

550 mL of 0.10 M ascorbic acid solution was separated into eleven 50-mL aliquots. The pH of each aliquot was adjusted by adding varying amounts of a 1.0 M NaOH solution. To obtain pH equilibrium, the ascorbic acid mixtures were allowed to rest for 3 hours. After equilibrating, 0.50 mL of each pH-adjusted ascorbic acid solution was added to a respective 50 mL of a 0.50 mM fresh gold salt (HAuCl₄) solution while stirring at 12000 rpm at room temperature. Vigorous stirring was maintained for 30 seconds. During this short time, the solutions became red with a transition rate depending on the [NaOH]/[AA] ratio, which ratio will hereafter be referred to as R₂. After the color change, the solutions were stirred at 3000 rpm for 30 minutes. The final products (11 distinct syntheses) were stored at room temperature. The final products remained stable for about one month.

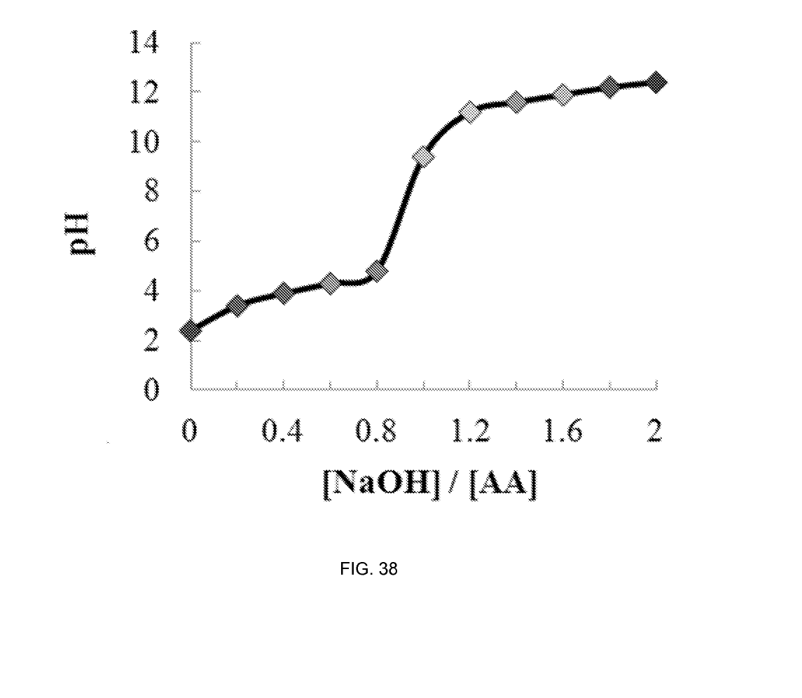

The gold nanoparticles were synthesized using R₂=[NaOH]/[AA] ratios varying from 0 to 2, leading to a variation of pH of the ascorbic acid solutions, which is shown in FIG. 38. The curve can be explained with the two pKₐ values of ascorbic acid: pKₐ₁=4.1, at the very beginning of the curve, and pKₐ₂=11.6 occurring at R₂≈1, which is consistent with the stoichiometry. Each point on the pH curve corresponds to a distinct nanoparticle synthesis.

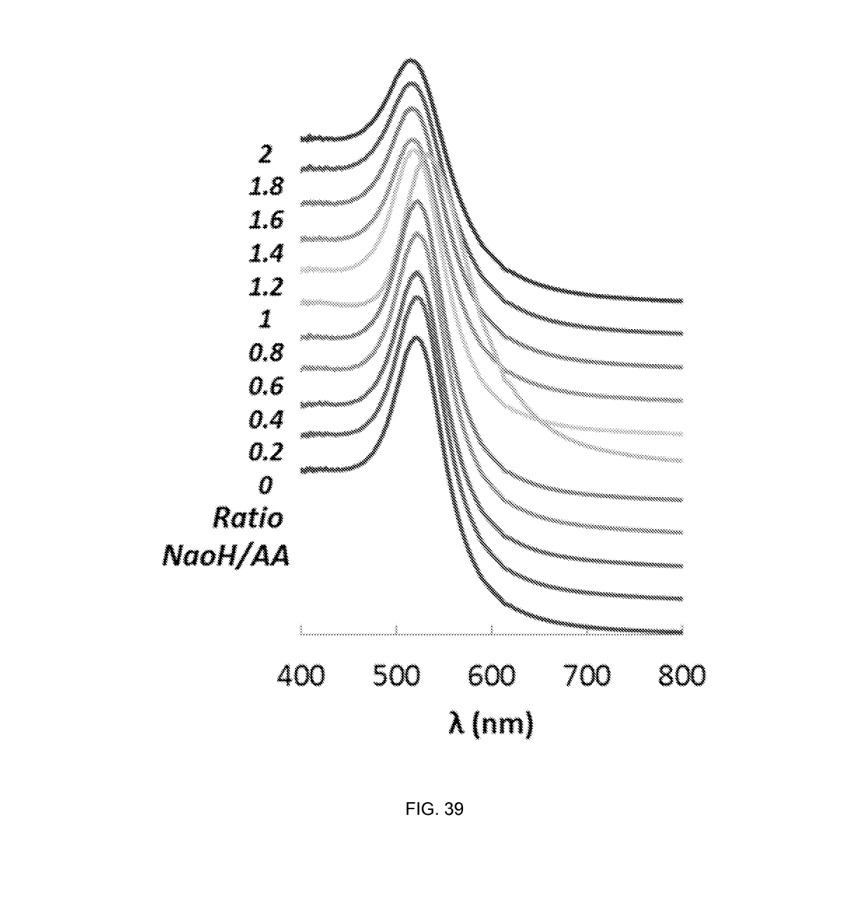

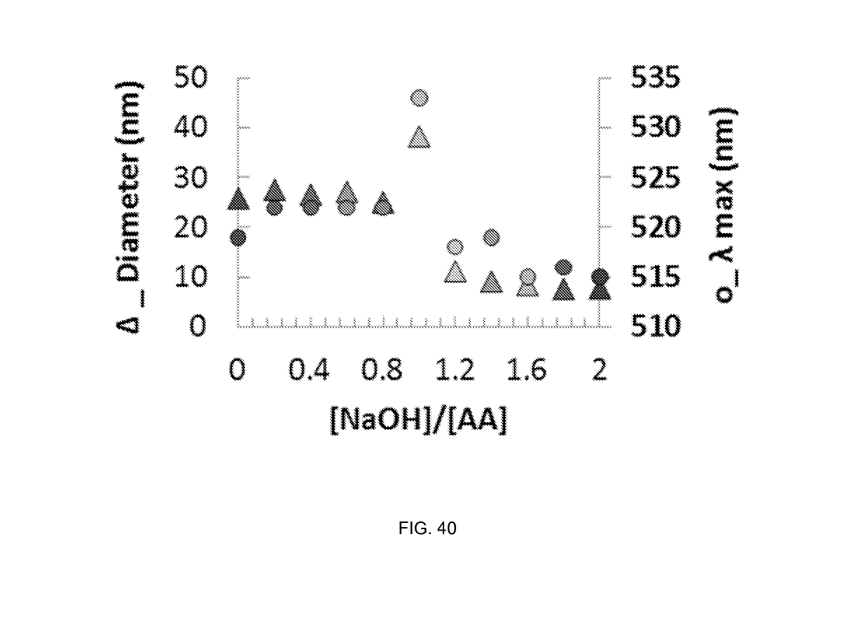

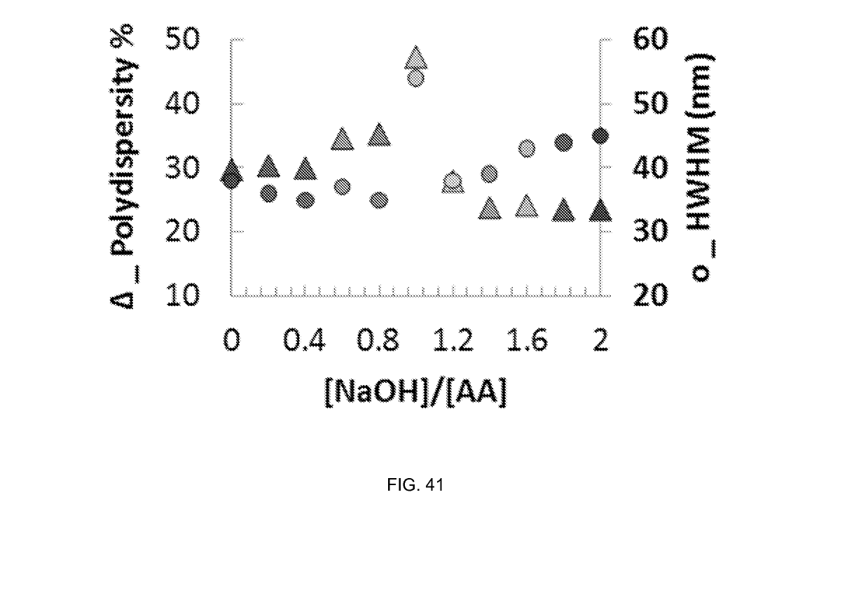

The extinction spectra of the particles synthesized at different R₂ ratios are presented in FIG. 39. The morphology of the nanoparticles and their optical properties, depending on R₂, are compared in FIGS. 40 and 41. FIG. 40 overlaps the plasmonic peak positions (λₘₐₓ, dots) and the diameter of the particles (triangles). The HWHM (half-width at half the maximum; dots) and the polydispersity (triangles) are plotted and shown in FIG. 41.

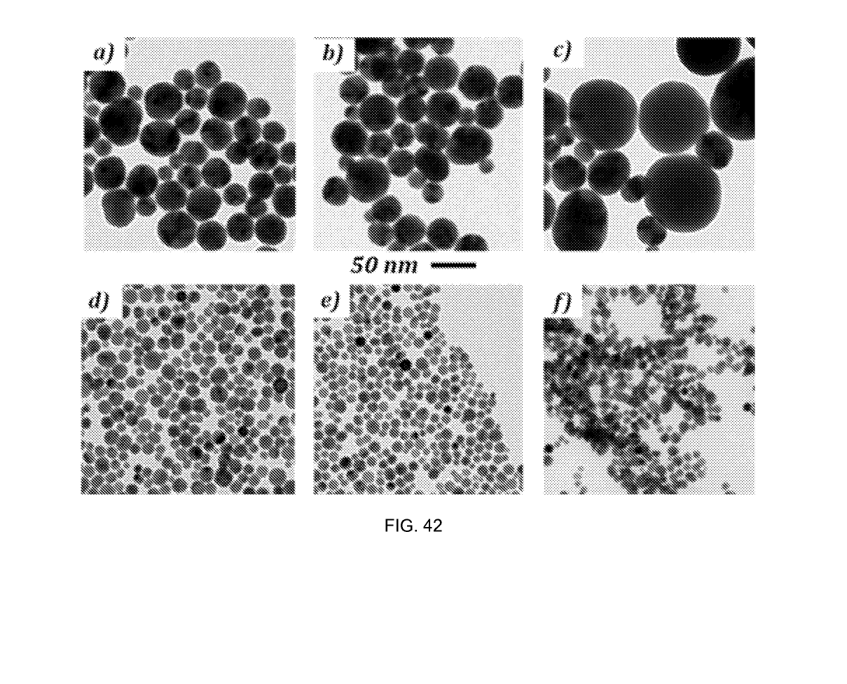

The diameters and polydispersity of the nanoparticles synthesized according to the present example are summarized in Table 7 below. FIG. 42 shows the TEM images of nanoparticles formed with a) R₂=0, b) R₂=0.6, c) R₂=1, d) R₂=1.2, e) R₂=1.6, and f) R₂=2.

TABLE 7

| R₂ | 0 | 0.6 | 1 | 1.2 | 1.6 | 2 |
|---|---|---|---|---|---|---|
| Diameter (nm) | 28 | 27 | 38 | 11 | 8.5 | 7.8 |
| Polydispersity | 27 | 34 | 47 | 28 | 24 | 23 |
| (%) | | | | | | |
| FIG. | 42a | 42b | 43c | 43d | 44e | 44f |

These data reveal two regimes: before the equivalence point, where the synthesized particles remain the same with a diameter of 30 nm and σ=30%, and after the equivalence point, where the size of the particles decrease from 11 nm and σ=28% to 7.8 and σ=23%.

Due to the very fast rate of reaction between the gold and the ascorbic acid, HAuCl₄ does not have enough time to convert into another complex HAuCl₄₋ₓ(OH)ₓ. Therefore, it is believed that its reactivity remains the same regardless of the pH of the solution. It has been reported (see D. V. Goia, Colloids and Surfaces A: Physicochem. Eng. Aspects 146, 1999, 139) that the redox potential of ascorbic acid is a function of the pH, that is, when the pH increases, the redox potential decreases, which in turn leads to an increase in the difference of redox potentials between AuCl₄ and the ascorbic acid, making the reaction faster. Without wishing to be bound by theory, it is believed that by increasing the reactivity between the gold salt and the reducing agent, more nuclei are created which explains the observation that the particles are smaller when pH increases. For pH<11.6, the slope of the curve E⁰=f(pH) is significantly less important than at a higher pH. Thus, it is believed that pH has more impact for R₂<1 than R₂>1 for this reason.

### Example 12

Silver nanoparticles were synthesized according to a method analogous to the method described in Example 7, except that 15 distinct syntheses were conducted and analyzed to investigate the effect of varying the amounts of base added to the ascorbic acid (AA) solution on the formation of the inventive silver nanoparticles.

750 mL of a 1.0 mM ascorbic acid (AA) solution was separated into fifteen 50-mL aliquots. The pH of each aliquot was adjusted by adding varying amounts of a 0.10 M NaOH solution. To equilibrate the pH, the ascorbic acid mixtures were each allowed to rest for 3 hours. After equilibrating, 0.50 mL of a 50.0 mM fresh silver salt (AgNO₃) solution was added to each of the fifteen pH-adjusted ascorbic acid solutions while stirring at 12000 rpm at room temperature. Vigorous stirring was maintained for 30 seconds. During this short time, the solutions became grey or yellow with a transition rate depending on the [NaOH]/[AA] ratio, hereafter referred to as the R₃ ratio. After the color change, the solutions were stirred at 3000 rpm for 30 minutes. During this time, the color became more and more intense, indicating that the reaction was not complete. The mixtures were kept undisturbed for 12 hours. The final products (15 distinct syntheses) were stored at room temperature, in the dark, and remained stable for about one month.

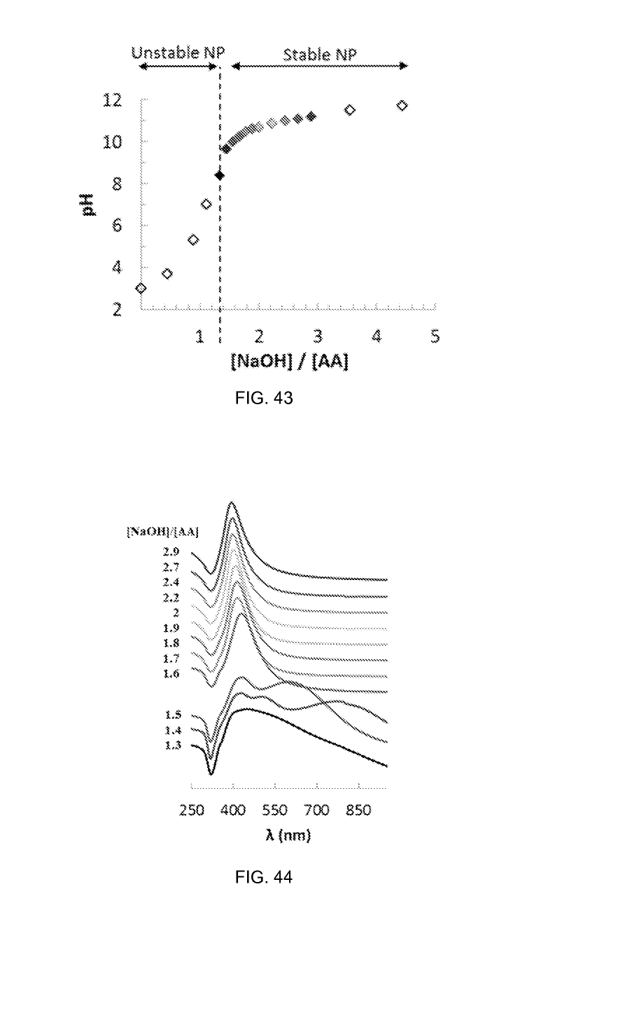

Inventive silver nanoparticles were prepared using R₃=[NaOH]/[AA] ratios from 1.3 to 3. A plot of pH as a function of R₃ is shown in FIG. 43. It was observed that for R₃<1.3, the synthesis does not generate stable nanoparticles and that it was necessary to reach a pH greater than 8 to reduce the silver into stable particles.

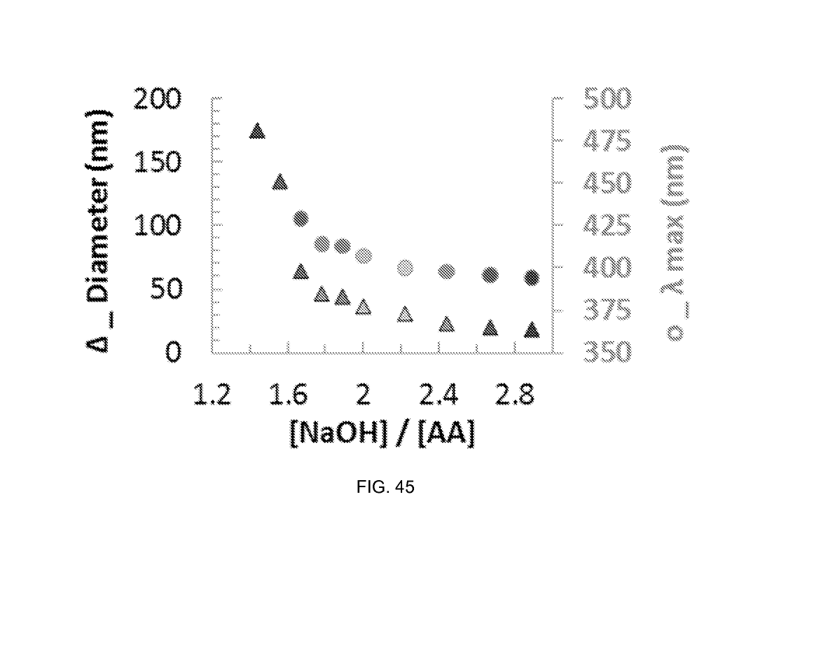

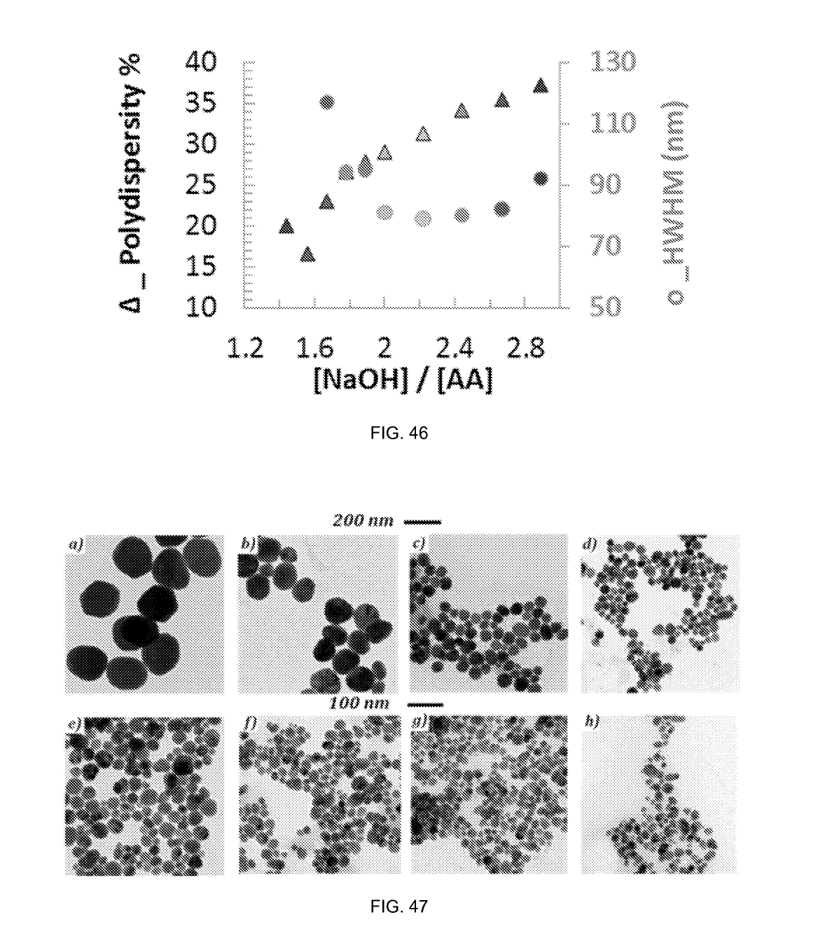

The extinction spectra of the particles synthesized at different R₃ ratios are presented in FIG. 44. The morphology of the nanoparticles and their optical properties, depending on R₃, are compared in FIGS. 45 and 46. FIG. 45 combines the plasmonic peak positions (λₘₐₓ, dots) and the diameters of the particles (triangles). The HWHM (half-width at half the maximum; dots) and the polydispersity (triangles) of the inventive silver nanoparticles are plotted and shown in FIG. 46.

The diameters and polydispersity of the nanoparticles synthesized according to the present example are summarized in Table 8 below. FIG. 47 shows the TEM images of nanoparticles formed with a) R₃=1.44, b) R₃=1.56, c) R₃=1.67, d) R₃=1.78, e) R₃=2, f) R₃=2.22, g) R₃=2.44, and h) R₃=2.67.

TABLE 8

| R₃ | 1.44 | 1.56 | 1.67 | 1.78 | 2 | 2.22 | 2.44 | 2.67 |
|---|---|---|---|---|---|---|---|---|
| Diameter (nm) | 175 | 135 | 64 | 46 | 36 | 31 | 23 | 20 |
| Polydispersity | 20 | 17 | 23 | 26 | 29 | 31 | 34 | 35 |
| (%) | | | | | | | | |
| FIG. | 47a | 47b | 47c | 47d | 47e | 47f | 47g | 47h |

It is believed that an increase of the ascorbic acid pH leads to the formation of smaller silver particles. For R₃<1.6, the spectra are broad and present several maxima. This behavior is believed to be due to the large size of the particles.

Without wishing to be bound by theory, it is believed when the size becomes large enough, the oscillations dictating the plasmonic response have a multipolar mode of resonance and lead to the appearance of several peaks (see V. Myroshnychenko, E. Carbó-Argibay, I. Pastoriza-Santos, J. Pérez-Juste, L. M. Liz-Marzán and F. J. Garcia de Abajo, Adv. Mater., 2008, 20, 4288-4293).

Due to the fast reaction rate between the silver salt and the ascorbic acid, it is believed that the redox potential of the metal remains the same regardless of pH. As pH of the ascorbic acid solution increases, the redox potential of the ascorbic acid decreases. This leads to an increase in the difference in redox potentials between the silver and the reducing agent, making the reaction faster. Without wishing to be bound by theory, it can be said that by increasing the reactivity between the silver salt and the reducing agent, more nuclei are created which explains the observation that the particles are smaller at higher pH.

As stated previously, for pH<11.6, the slope of the curve E⁰=f(pH) is significantly less important than that at higher pH. The reactivity between the silver salt and the ascorbic acid solution is significant at R₃>1. Indeed, the comparison of the redox potential of HAuCl₄ and AgNO₃ shows that the silver salt is less reactive than the gold salt (see D. V. Goia, Colloids and Surfaces A: Physicochem. Eng. Aspects 146, 1999, 139; and D. V. Goia, J. Mater. Chem., 2004, 14, 451-458).

1. A method for synthesizing metal nanoparticles, the method comprising:
(a) preparing a metal precursor mixture comprising a metal precursor compound and a first aqueous liquid medium,
(b) preparing a reducing agent mixture comprising a reducing agent and a second aqueous liquid medium,
(c) optionally adding an acid or a base to the mixture prepared in step (a) or to the mixture prepared in step (b),
wherein the metal precursor mixture and the reducing agent mixture are both free of stabilizing agent and free of seed particles,
(d) combining the metal precursor mixture with the reducing agent mixture so as to allow the metal precursor compound to react with the reducing agent,
thereby synthesizing the metal nanoparticles.

2. The method according to claim 1, wherein the metal precursor compound comprises a metal salt or metal acid wherein the metal is part of an anion.

3. The method according to claim 1, wherein the metal precursor compound comprises silver nitrate, tetrachloroauric acid, hexachloroplatinic acid, chloropalladic acid, tetrachloroferric acid (HFeCl4), or a hydrate thereof.

4.-7. (canceled)

8. The method according to claim 1, wherein a base is added to the metal precursor mixture or to the reducing agent mixture.

9. The method according to claim 8, wherein the base added to the metal precursor mixture or to the reducing agent mixture comprises a hydroxide ion.

10. The method according to claim 9, wherein the base added to the metal precursor mixture or to the reducing agent mixture comprises sodium hydroxide.

11. (canceled)

12. (canceled)

13. The method according to claim 8, wherein the molar ratio of base-to-metal precursor compound is from about 0.1:1 to about 6.0:1.

14. The method according to claim 13, wherein the molar ratio of base-to-metal precursor compound is from about 0.1:1 to about 4.4:1.

15. The method according to claim 13, the molar ratio of base-to-metal precursor compound is from about 4.5:1 to about 6.0:1.

16. The method according to claim 1, wherein the reducing agent comprises a carboxylic acid, or a derivative thereof.

17. The method according to claim 16, wherein the reducing agent comprises ascorbic acid, citric acid, erythorbic acid, or a salt thereof.

18.-20. (canceled)

21. The method according to claim 1, wherein the molar ratio of reducing agent-to-metal precursor compound is from about 0.5:1 to about 16:1.

22. (canceled)

23. (canceled)

24. Metal nanoparticles synthesized by the method according to claim 1.

25. (canceled)

26. (canceled)

27. The metal nanoparticles according to claim 24, wherein the polydispersity is from about 1% to about 70%.

28. (canceled)

29. A method for modifying the surface of metal nanoparticles, the method comprising:
contacting the metal nanoparticles in accordance with claim 24 with at least one stabilizing agent,
thereby modifying the surface of the metal nanoparticles.

30.-32. (canceled)

33. The method according to claim 29, wherein the step of contacting the metal nanoparticles with at least one stabilizing agent comprises:
(1) adding the at least one stabilizing agent or a stabilizing agent mixture, comprising the at least one stabilizing agent and a first liquid medium, to a nanoparticle mixture, comprising the metal nanoparticles and a second liquid medium,
(2) centrifuging the combination formed in step (1), and
(3) removing the supernatant.

34.-36. (canceled)

37. An electronic device comprising the metal nanoparticles according to claim 24.

38. (canceled)

39. A catalyst comprising metal nanoparticles according to claim 24, and, optionally, a support.

40. The method according to claim 8, wherein the molar ratio of base-to-reducing agent is from about 0:1 to about 3:1.

41. The method according to claim 40, wherein the molar ratio of base-to-reducing agent is from about 0.1:1 to about 3:1.
